(19) United States
(12) Patent Application Publication
(10) Pub. No.: US 2019/0280143 A1
(43) Pub. Date: Sep. 12, 2019

(54) CHIRPED DISTRIBUTED BRAGG REFLECTORS FOR PHOTOVOLTAIC CELLS AND OTHER LIGHT ABSORPTION DEVICES

(71) Applicant: SOLAR JUNCTION CORPORATION, Geneva, AZ (US)

(72) Inventors: DING DING, CHANDLER, AZ (US); PHILIP DOWD, GILBERT, AZ (US); FERRAN SUAREZ, CHANDLER, AZ (US); DAVID TANER BILIR, REDWOOD CITY, CA (US); AYMERIC MAROS, SAN FRANCISCO, CA (US)

(21) Appl. No.: 16/298,402

(22) Filed: Mar. 11, 2019

Related U.S. Application Data
(60) Provisional application No. 62/641,482, filed on Mar. 12, 2018.

(51) Int. Cl. H01L 31/076; H01L 31/056; H01L 31/0304; H01L 31/105; H01L 31/0232

(52) U.S. Cl. CPC H01L 31/076; H01L 31/056; H01L 31/02327; H01L 31/105; H01L 31/03046

(57) ABSTRACT

Semiconductor light absorption devices such as multi junction photovoltaic cells include a chirped distributed Bragg reflector beneath a junction. The chirped distributed Bragg reflector provides a high reflectivity over a broad range of wavelengths and has improved angular tolerance so as to provide increased absorption within an overlying junction over a broader range of wavelengths and incident angles.

This application claims the benefit under 35 U.S.C. § 119(e) of U.S. Provisional Application No. 62/641,482 filed on Mar. 12, 2018, which is incorporated by reference in its entirety.

### FIELD

The present invention relates to semiconductor light absorption devices having a chirped distributed Bragg reflector, and in particular, multi junction photovoltaic cells having a chirped distributed Bragg reflector disposed beneath a junction. The chirped distributed Bragg reflector provides a high reflectivity over a broad range of wavelengths and has improved angular tolerance so as to provide increased absorption within a device over a broader range of wavelengths and incident angles.

### BACKGROUND

Multijunction photovoltaic cells based primarily on compound semiconductor materials are known to produce the highest efficiency cells, making them highly suited to terrestrial applications such as concentrating photovoltaic (CPV) systems and to space applications. Multijunction photovoltaic cells (100), as shown in FIGS. 1 and 2A-D, include multiple diodes in series connection, known in the art as junctions (106, 107 and 108 in FIG. 1), are realized by growing thin regions of epitaxy in stacks on semiconductor substrates. Each junction in a stack possesses a unique band gap and is optimized for absorbing a different portion of the solar spectrum, thereby improving efficiency of solar energy conversion. These junctions can be chosen from a variety of semiconductor materials with different optical and electrical properties to absorb different portions of the solar spectrum. The materials are arranged such that the band gaps of the junctions become progressively lower from the top junction (106) to the bottom junction (108). Thus, high-energy photons are absorbed in the top junction and less energetic photons pass through to the lower junctions where the low energy photons are absorbed. In each junction, electron-hole pairs are generated, and current is collected at the ohmic contacts of the photovoltaic cell (2 and 52 in FIG. 1). Semiconductor materials used to form the junctions include, for example, germanium and alloys of one or more elements from Group III and Group V of the periodic table. Examples of these alloys include indium gallium phosphide, indium phosphide, gallium arsenide, aluminum gallium arsenide, indium gallium arsenide, gallium antimonide, indium phosphide, and dilute nitride compounds. For ternary and quaternary compound semiconductors, a wide range of alloy ratios can be used. Tunnel junctions are used between neighboring cells to interconnect the cells.

Dilute nitrides are advantageous as photovoltaic cell materials because the lattice constant can be varied to match a broad range of substrates and/or junctions formed from semiconductor materials other than dilute nitrides. Because dilute nitrides provide high quality, lattice-matched and band gap-tunable junctions, photovoltaic cells comprising dilute nitride junctions can achieve high conversion efficiencies on industry-standard substrates. The increase in efficiency is largely due to less light energy being lost as heat, because the additional junctions allow more of the incident photons to be absorbed by semiconductor materials with band gaps closer to the energy of the incident photons. In addition, there will be lower series resistance losses in these multijunction photovoltaic cells compared to other photovoltaic cells due to the lower operating currents. At higher concentrations of sunlight, the reduced series resistance losses become more pronounced. Depending on the band gap of the bottom junction, the collection of a wider range of photons in the photovoltaic spectrum may also contribute to the increased efficiency. Dilute nitride materials may also be used as absorber layers in infrared photodetectors.

Examples of dilute nitrides include GaInNAsSb, GaInNAsBi, GaInNAsSbBi, GaNAsSb, GaNAsBi and GaNAsSbBi. The lattice constant and band gap of a dilute nitride can be controlled by the relative fractions of the different Group IIIA and Group VA elements. Furthermore, high quality material may be obtained by selecting the composition around a specific lattice constant and band gap, while limiting the total antimony and/or bismuth content, for example, to no more than 20 percent of the Group V lattice sites. Antimony and bismuth are believed to act as surfactants that promote smooth growth morphology of the III-AsNV dilute nitride alloys. Thus, by tailoring the compositions (i.e., the elements and quantities) of a dilute nitride material, a wide range of lattice constants and band gaps may be obtained. The band gaps and compositions can be tailored so that the short-circuit current density produced by a dilute nitride junction in a photovoltaic cell will be the same as or slightly greater than the short-circuit current density of each of the other junctions in the photovoltaic cell. The bandgaps and compositions of a dilute nitride may also be tailored to provide an improved detector responsivity for a photodetector.

The junction in a photovoltaic cell with the lowest current is the current limiting junction, and limits the maximum current flow in the device, thereby reducing efficiency. Low currents may be generated by cells in which the optical absorption coefficient is weak, or by junctions in which thin junctions are needed for carrier collection or end-of-life concerns. Therefore, increasing the absorption within such a junction, and hence the current generated by the junction, is desirable.

Distributed Bragg reflectors (DBRs) have been proposed to improve the performance of junctions in a multijunction photovoltaic cell. A DBR underlying a junction can be designed to reflect unabsorbed light back into the junction, which can be absorbed and contribute to improved current generation.

U.S. Pat. Nos. 8,716,493 and 9,257,586 disclose a DBR underlying a GaInNAs J2 junction of a 3J device. For a 3J photovoltaic cell to function with reasonable efficiency, the band gaps for a J1/GaInNAs J2/Ge 3J photovoltaic cell can be, for example, 1.9 eV/1.35-1.4 eV/0.7 eV. The reflectivity spectrum shows that a high reflectivity greater than 60% can be achieved over a wavelength range of about 100 nm from about 800 nm to 900 nm, with wavelengths longer than about 900 nm transmitted to the underlying Ge junction with low loss.

U.S. Pat. No. 9,018,521 discloses a DBR underlying a first junction J1 of an inverted metamorphic, non-lattice-matched, multijunction (IMM) photovoltaic cell.

U.S Application Publication No. 2010/0147366 discloses DBRs underlying a second junction J2 and a third junction J3 of an inverted metamorphic, non-lattice-matched, multijunction (IMM) photovoltaic cell.

U.S. Application Publication No. 2017/0200845 discloses photovoltaic cells with a first DBR and a second DBR, where the DBRs reflect at different wavelength ranges, underlying a dilute nitride cell in a multijunction photovoltaic cell.

However, the reflectivity bandwidth of semiconductor DBRs is typically limited to about 100 nm. Although some work mentions wider reflectivity bandwidths, specific designs to achieve wider bandwidths are not described. For example, while a dual-layer DBR appears to be operable over a wavelength range of about 150 nm, designs that are capable of extending reflectivity across a larger wavelength range, for example, corresponding to the absorption spectrum in the dilute nitride junction, are not described.

Dilute nitride heterostructures can exhibit high background doping levels, low minority carrier lifetimes and short minority carrier diffusion lengths, which can reduce the photocarrier collection volume within the device. This can limit the short circuit current density (Jsc) that can be generated by the dilute nitride, and also reduces cell efficiency. Material quality can be improved by decreasing the nitride content, but this increases the bandgap of the material, changes the absorption spectrum, and reduces the absorption level. Reflectors can be used to reflect unabsorbed photons back into a thinner absorption region, effectively increasing the absorption level for a thin region. Reflectors can also be used to compensate for reduced absorption at longer wavelengths that are associated with larger bandgap material. It would be preferable to achieve reflectivity over a wider wavelength range that covers the entire absorption range for a particular junction.

The reflectivity spectrum of a DBR can shift in both magnitude and in operable wavelength at different angles of incidence. This can decrease the effect of the reflector on a device. In some applications where the angle of incidence of the light changes over time, the effect of a DBR can be limited. In systems such as concentrated photovoltaic (CPV) systems using optics, where light may be brought in over a broader angular range to increase efficiency, or where roughened surfaces are used to decrease reflectivity at the air-semiconductor interface, the broader range of incident angles means light is not reflected back as efficiently.

Therefore, new reflector structures for optical absorption devices, including photovoltaic systems and photodetectors are desired that provide a broader reflectivity spectrum and that are also less sensitive to angular changes of the incident light.

### SUMMARY

According to the present invention, semiconductor structures comprise: a light absorbing region comprising a high wavelength absorption edge; and a chirped distributed Bragg reflector underlying the light absorbing region, wherein the chirped distributed Bragg reflector is configured to provide: a reflectivity greater than 50% at an incident angle within a range of ±45 degrees from normal throughout; a full-width-half-maximum wavelength range of 100 nm or greater; and a transmissibility greater than 80% at a wavelength that is 50 nm longer than the high wavelength absorption edge of the overlying light absorbing region.

According to the present invention, semiconductor structures comprise a chirped distributed Bragg reflector; and a light absorbing region overlying the chirped distributed Bragg reflector.

According to the present invention, multijunction photovoltaic cells comprise the semiconductor structure according to the present invention; a first doped layer underlying the chirped distributed Bragg reflector; and a second doped layer overlying the light absorbing region.

According to the present invention, semiconductor devices comprise the semiconductor structure according to the present invention.

According to the present invention, multijunction photovoltaic cells comprise the semiconductor structure according to the present invention.

According to the present invention, photovoltaic modules comprise the multijunction photovoltaic cell according to the present invention.

According to the present invention, power systems comprise the photovoltaic module according to the present invention.

According to the present invention, methods of fabricating a semiconductor structure comprise: providing a semiconductor substrate; depositing a chirped semiconductor reflector on the semiconductor substrate, and depositing a first optical absorbing region on the reflector, wherein the first optical absorbing region has a bandgap and an associated absorption spectrum, and wherein the chirped semiconductor reflector reflects a wavelength range back into the first optical absorbing region, that is absorbable by said absorbing region.

### BRIEF DESCRIPTION OF THE DRAWINGS

Those skilled in the art will understand that the drawings described herein are for illustration purposes only. The drawings are not intended to limit the scope of the present disclosure.

FIG. 1 shows a cross-section of an example of a prior art multijunction photovoltaic cell.

FIG. 2A shows a schematic of a cross-section of a multijunction photovoltaic cell with three junctions.

FIGS. 2B and 2C show schematic cross-sections of multijunction photovoltaic cells with four junctions.

FIG. 2D shows a schematic cross-section of a multijunction photovoltaic cell with five junctions.

FIG. 3 shows a schematic cross-section of an optical absorption device according to the present disclosure.

FIG. 4 shows a schematic cross-section of a three-junction photovoltaic cell according to the present disclosure.

FIG. 5 shows a schematic cross-section of a four-junction photovoltaic cell according to the present disclosure.

FIG. 6 shows an example of compositions and functions of certain layers that may be present in a 3J multijunction photovoltaic cell comprising AlInGaP/(Al,In)GaAs/GaInNAsSb.

FIG. 7 shows an example of compositions and functions of certain layers that may be present in a 4J multijunction photovoltaic cell comprising AlInGaP/(Al,In)GaAs/GaInNAsSb/Ge.

FIG. 8 shows reflectivity spectra for a non-chirped DBR design with fixed layer thicknesses, and different numbers of dielectric pairs.

FIG. 9 shows a schematic cross-section of a chirped DBR reflector in accordance with an embodiment of the present disclosure.

FIG. 10 shows DBR reflectivity spectra for two chirped DBRs according to the present disclosure.

FIG. 11 shows the simulated wavelength-dependent quantum efficiency for a dilute nitride J3 junction and for a (Si,Sn)Ge J4 junction of a 4J photovoltaic cell, with and without a chirped DBR between the dilute nitride J3 junction and the (Si,Sn)Ge J4 junction.

FIG. 12 shows the simulated wavelength dependent absorption difference for a dilute nitride J3 junction derived from the simulation results shown in FIG. 11.

FIG. 13 shows the wavelength-dependent quantum efficiency for a baseline dilute nitride J3 junction and a thinner dilute nitride J3 junction with an underlying chirped DBR.

FIG. 14 shows a non-chirped DBR reflectivity spectrum and a chirped DBR reflectivity spectrum according to an embodiment of the present disclosure.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized, and structural, logical, and electrical changes may be made without departing from the scope of the invention. The various embodiments disclosed herein are not necessarily mutually exclusive, as some disclosed embodiments may be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard variation found in their respective testing measurements.

Also, it should be understood that any numerical range recited herein is intended to include all sub-ranges encompassed therein. For example, a range of “1 to 10” is intended to include all sub-ranges between (and including) the recited minimum value of about 1 and the recited maximum value of about 10, that is, having a minimum value equal to or greater than about 1 and a maximum value of equal to or less than about 10.

“Lattice matched” refers to semiconductor layers for which the in-plane lattice constants of adjoining materials in their fully relaxed states differ by less than 0.6% when the materials are present in thicknesses greater than 100 nm. Further, junctions that are substantially lattice matched to each other means that all materials in the junctions that are present in thicknesses greater than 100 nm have in-plane lattice constants in their fully relaxed states that differ by less than 0.6%. In an alternative meaning, substantially lattice matched refers to the strain. As such, base layers can have a strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. Strain refers to compressive strain and/or to tensile strain.

The term “pseudomorphically strained” as used herein means that layers made of different materials with a lattice parameter difference can be grown on top of other lattice matched or strained layers without generating misfit dislocations. Pseudomorphically strained layers can have lattice parameters that differ, for example, by up to +/−2%, by up to +/−1%, or by up to +/−0.5%. Lattice parameters can differ by up to +/−0.2%.

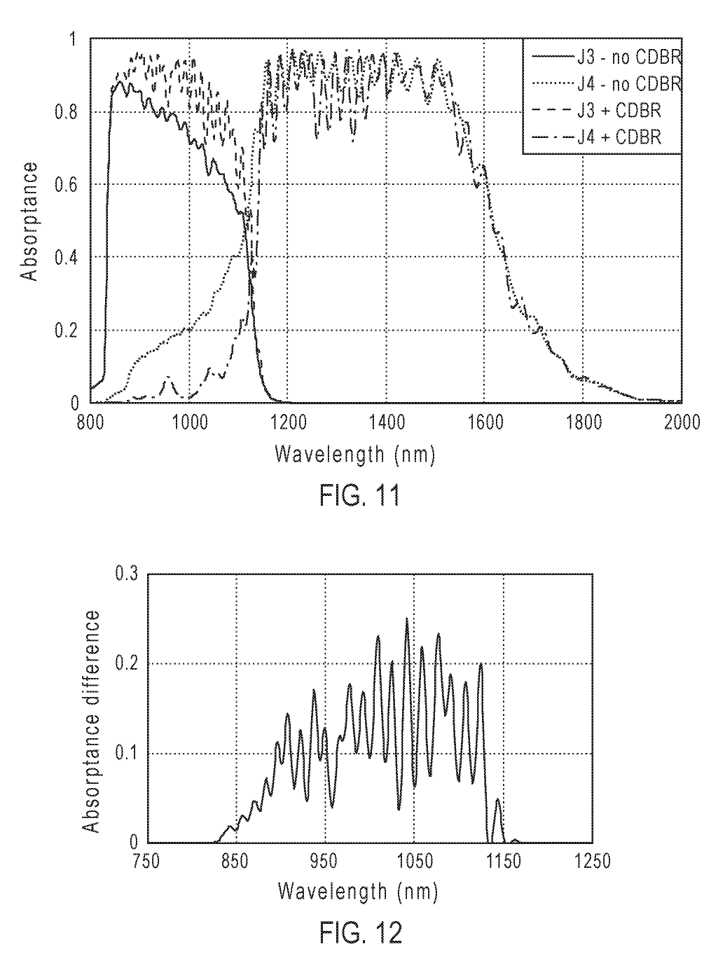

The term “long wavelength absorption edge” refers to the longest wavelength that may be absorbed by a semiconductor material such as light absorbing region, which is related to the bandgap energy of the semiconductor. Light at longer wavelengths than the long wavelength absorption edge has an associated energy that is less than the bandgap of the semiconductor material, and thus is not absorbed by the material. The long wavelength absorption edge more specifically refers to the wavelength at the long wavelength edge of the absorption spectrum at which the absorption is 50% that of the maximum absorption within the absorption spectrum of a semiconductor layer such as a light absorbing region. For example, referring to FIG. 11, the long wavelength absorption edge for the J3 junction is about 1150 nm, and for the J4 junction about 1650 nm.

The term “short wavelength absorption edge” refers to the shortest wavelength that may be absorbed by a semiconductor material within a device and contributes to current generation in that semiconductor material. More specifically, the short wavelength absorption edge refers to the wavelength at the short wavelength edge of the absorption spectrum at which the absorption is 50% that of the maximum absorption within the absorption spectrum of a semiconductor layer such as a light absorbing region, For example, referring to FIG. 11, the short wavelength absorption edge for the J3 junction is about 825 nm, and for the J4 junction about 1150 nm.

The devices and methods of the present invention facilitate the manufacture of high quality dilute nitride-containing semiconductor devices such as multijunction photovoltaic cells. The disclosure teaches devices with a chirped reflector underlying a dilute nitride layer such as a dilute nitride junction of a multijunction photovoltaic cell and methods of making such devices. Semiconductors such as multijunction photovoltaic cells comprising a chirped reflector underlying a dilute nitride layer exhibit improved performance. The chirped reflector can be a chirped DBR (CDBR).

Semiconductor devices provided by the present disclosure can comprise a first semiconductor layer comprising a dilute nitride, a chirped reflector underlying the first semiconductor layer; and a second semiconductor layer underlying the chirped reflector, wherein the first semiconductor layer, the chirped reflector, and the second semiconductor layer are lattice matched to each of the other layers. Examples of semiconductor devices that can incorporate the three-layer structure include power converters, photodetectors, transistors, lasers, light emitting diodes, optoelectronic devices, and photovoltaic cells such as a multijunction photovoltaic cells. A dilute nitride layer can comprise GaInNAs, GaInNAsSb, GaInNAsBi, GaInNAsSbBi, GaNAsSb, GaNAsBi, or GaNAsSbBi. A dilute nitride layer can comprise GaInNAsSb, GaInNAsBi, or GaInNAsSbBi. A dilute nitride layer can comprise GaInNAsSb.

A multijunction photovoltaic can comprise at least three junctions, such as a three junction 3J, a four junction (4J), a five junction (5J), or a six junction (6J) photovoltaic cell, in which at least one of the junctions comprises a dilute nitride. A multijunction photovoltaic cell can comprise, for example, one dilute nitride junction or two dilute nitride junctions.

A multijunction photovoltaic cell can comprise a dilute nitride junction, a CDBR layer underlying the dilute nitride junction, and a (Si,Sn)Ge junction underlying the CDBR layer. In multijunction photovoltaic cells comprising two dilute nitride junctions, a separate CDBR layer can underlie each of the dilute nitride junctions, or a single CDBR layer can underlie the lowermost dilute nitride junction.

A dilute nitride junction can have a thickness, for example, from 0.5 microns to 4 microns, from 0.5 microns to 3.5 microns, from 0.5 microns to 3 microns, from 0.5 microns to 2.5 microns, from 0.5 microns to 2 microns, from 0.5 microns to 1.5 microns, or from 1 microns to 2 microns.

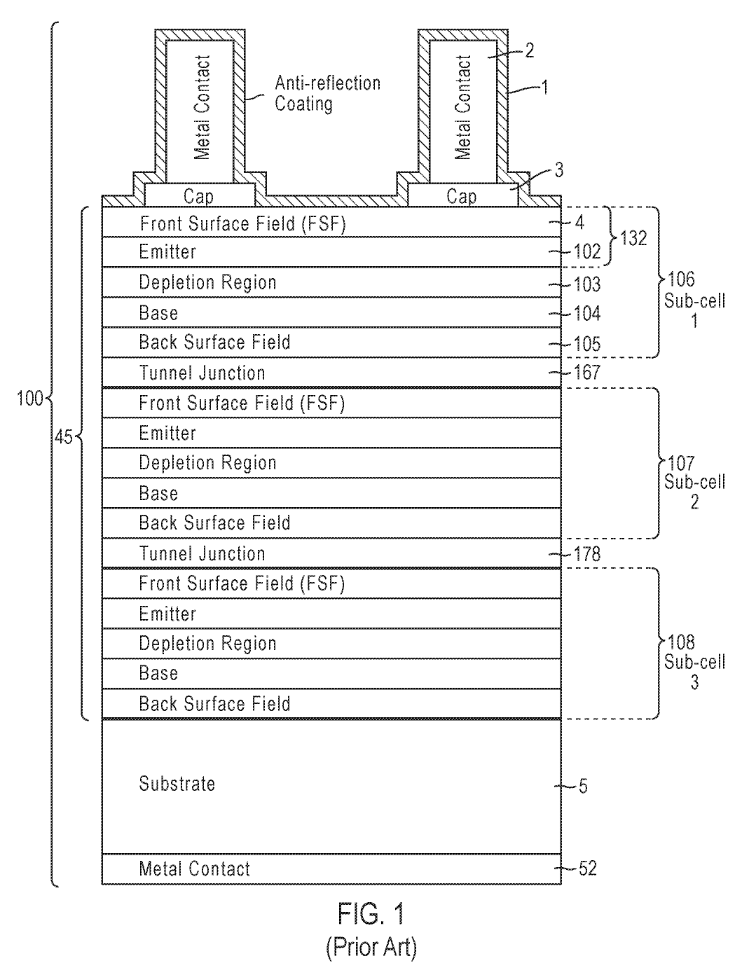

As shown in FIG. 1, a multijunction photovoltaic cell 100 can include substrate 5, back metal contact 52, top metal contact 2 including cap regions 3 and heteroepitaxial layers 45 forming each of the junctions. An ARC 1 overlies metal contact 2, cap regions 3, and the front surface of the uppermost junction 106. The multijunction photovoltaic cell shown in FIG. 1 includes three junctions 106, 107, and 108. Each junction can comprise a front surface field 4 and emitter 102 forming element 132, depletion region 103, base 104, back surface field 105, and tunnel junction 167. An ARC 1 can cover the top surface of the multijunction photovoltaic cell. Tunnel junction 178 interconnects second junction 107 and third junction 108. Heteroepitaxial layers 45 overlie substrate 5 and a metal contact 52 is disposed on the back side of substrate 5. Substrate 5 can also be an active junction of the multijunction photovoltaic cell such as when the substrate comprises (Si,Sn)Ge.

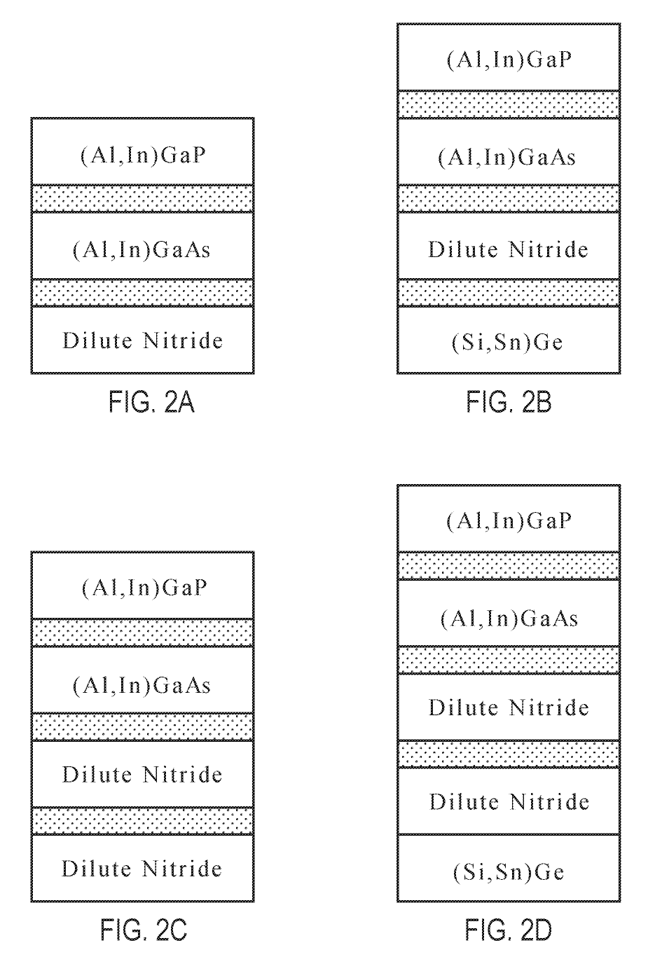

FIGS. 2A-2D show schematics of multijunction photovoltaic cells comprising at least one dilute nitride junction. FIG. 2A shows a three-junction 3J photovoltaic cell comprising a (Al,In)GaP junction, a (Al,In)GaAs junction, and a dilute nitride junction. FIG. 2B shows a four-junction 4J photovoltaic cell comprising a (Al,In)GaP junction, a (Al,In)GaAs junction, a dilute nitride junction, and a (Si,Sn)Ge junction. The (Al,In)GaP junction can have a band gap from 1.9 eV to 2.2 eV; the (Al,In)GaAs junction can have a band gap from 1.4 eV to 1.7 eV; the dilute nitride junction can have a band gap from 0.9 eV to 1.3 eV; and the (Si,Sn)Ge junction can have a band gap from 0.7 eV to 0.9 eV. FIG. 2C shows a four-junction 4J photovoltaic cell comprising a (Al,In)GaP junction, a (Al,In)GaAs junction, and two dilute nitride junctions. The (Al,In)GaP junction can have a band gap from 1.9 eV to 2.2 eV; the (Al,In)GaAs junction can have a band gap from 1.4 eV to 1.7 eV; the dilute nitride junction (J3) can have a band gap from 1.0 eV to 1.3 eV; and the dilute nitride junction (J4) can have a band gap from 0.7 eV to 1.1 eV. FIG. 2D shows a five-junction 5J photovoltaic cell comprising a (Al,In)GaP junction, a (Al,In)GaAs junction, two dilute nitride junctions, and a (Si,Sn)Ge junction.

A multijunction photovoltaic cell can be configured such that the junction having the highest band gap faces the incident solar radiation, with junctions characterized by increasingly lower band gaps situated underlying or beneath the uppermost junction. For optimal efficiency, the specific band gaps of the junctions are dictated, at least in part, by the band gap of the bottom junction, the thicknesses of the junction layers, and the spectrum of incident light. All junctions within a multijunction photovoltaic cell can be substantially lattice-matched to each of the other junctions. A multijunction photovoltaic cell may be fabricated on a substrate such as a (Si,Sn)Ge substrate. The substrate can comprise gallium arsenide, indium phosphide, gallium antimonide, (Si,Sn)Ge, silicon, or an engineered substrate such as a buffered silicon substrate. Examples of buffers that can be grown on silicon to produce a substrate with a lattice constant that is equal to or approximately equal to the lattice constant of Ge or GaAs include SiGeSn, and rare-earth oxides (REOs). Each of the junctions can be substantially lattice-matched to a substrate.

Dilute nitrides are advantageously used as photovoltaic cell materials because the lattice constant can be varied to substantially match a broad range of substrates and/or junctions formed from semiconductor materials other than dilute nitrides. Examples of dilute nitrides include GaInNAs, GaInNAsSb, GaInNAsBi, GaInNAsSbBi, GaNAsSb, GaNAsBi and GaNAsSbBi. The lattice constant and band gap of a dilute nitride can be controlled by the relative fractions of the different group IIIA and group VA elements. Thus, by tailoring the compositions (i.e., the elements and quantities) of a dilute nitride material, a wide range of lattice constants and band gaps may be obtained. Further, high quality material may be obtained by adjusting the composition around a specific lattice constant and band gap, while limiting the total Sb and/or Bi content, for example, to no more than 20 percent of the Group V lattice sites, such as no more than 10 percent of the Group V lattice sites. Sb and Bi are believed to act as surfactants that promote smooth growth morphology of the III-AsNV dilute nitride alloys. In addition, Sb and Bi can facilitate uniform incorporation of nitrogen and minimize the formation of nitrogen-related defects. The incorporation of Sb and Bi can enhance the overall nitrogen incorporation and reduce the alloy band gap. However, Sb and Bi can create additional defects and therefore it is desirable that the total concentration of Sb and/or Bi be limited to no more than 20 percent of the Group V lattice sites. Further, the limit to the Sb and Bi content decreases with decreasing nitrogen content. Alloys that include indium can have even lower limits to the total content because In can reduce the amount of Sb needed to tailor the lattice constant. For alloys that include In, the total Sb and/or Bi content may be limited to no more than 5 percent of the Group V lattice sites, in certain embodiments, to no more than 1.5 percent of the Group V lattice sites, and in certain embodiments, to no more than 0.2 percent of the Group V lattice sites.

For example, Ga₁₋ₓInₓN_{y}As_{1-y-z}Sb_{z}, disclosed in U.S. Pat. No. 8,912,433, which is incorporated by reference in its entirety, can produce a high-quality material when substantially lattice-matched to a GaAs or a Ge substrate in the composition range of 0.07≤x≤0.18, 0.025≤y≤0.04 and 0.001≤z≤0.03, with a band gap of at least 0.9 eV such as within a range from 0.9 eV to 1.1 eV. U.S. Pat. Nos. 8,697,481, and 8,962,993, each of which is incorporated by reference in its entirety, disclose Ga₁₋ₓInₓN_{y}As_{1-y-z}Sb_{z} in the composition range of 0≤x≤0.24, 0.001≤y≤0.07 and 0.001≤z≤0.20, with bandgap between 0.7 eV and 1.4 eV. Co-pending U.S. Application No. 62/564,124, filed Sep. 27, 2017, which is incorporated by reference in its entirety, discloses dilute nitride junctions comprising Ga₁₋ₓInₓN_{y}As_{1-y-z}Sb_{z}, where x, y and z fall within the ranges 0≤x≤0.4, 0≤y≤0.07 and 0≤z≤0.2, respectively. In some embodiments, x, y, and z can fall within the ranges of 0.01≤x≤0.4, 0.02≤y≤0.06 and 0.001≤z≤0.04, respectively.

In dilute nitrides provided by the present disclosure, the N content is not more than 10 percent of the Group V lattice sites, not more than 7 percent, not more than 5.5 percent, not more than 4%, and in certain embodiments, not more than 3.5 percent.

In dilute nitrides provided by the present disclosure, the dilute nitrides can comprise Ga₁₋ₓInₓN_{y}As_{1-y-z}Sb_{z}, where x, y and z fall within the ranges 0≤x≤0.4, 0≤y≤0.1 and 0≤z≤0.2, respectively. In some embodiments, x, y and z can fall within the ranges of 0.01≤x≤0.4, 0.02≤y≤0.07 and 0.001≤z≤0.04, respectively.

Embodiments of the present disclosure include dilute nitride junctions, comprising, for example, GaInNAsSb, GaInNAsBi, or GaInNAsBiSb in the base layer that can be incorporated into multijunction photovoltaic cells that perform at high efficiencies. The band gaps of the dilute nitrides can be tailored by varying the composition while controlling the overall content of Sb and/or Bi. Thus, a dilute nitride junction with a band gap suitable for integrating with other junction may be fabricated while maintaining substantial lattice-matching to each of the other junctions and to the substrate. The band gaps and compositions can be tailored so that the Jsc produced by the dilute nitride junctions will be the same as or slightly greater than the Jsc of each of the other junctions in the photovoltaic cell. Because dilute nitrides provide high quality, lattice-matched and band gap-tunable junctions, photovoltaic cells comprising dilute nitride junctions can achieve high conversion efficiencies. The increase in efficiency is largely due to less light energy being lost as heat, as the additional junctions allow more of the incident photons to be absorbed by semiconductor materials with band gaps closer to the energy of the incident photons. In addition, there will be lower series resistance losses in these multijunction photovoltaic cells compared to other photovoltaic cells due to the lower operating currents. At higher concentrations of sunlight, the reduced series resistance losses become more pronounced. Depending on the band gap of the bottom junction, the collection of a wider range of photons in the solar spectrum may also contribute to the increased efficiency.

Due to interactions between the different elements, as well as factors such as the strain in the dilute nitride layer, the relationship between composition and band gap for a dilute nitride such as Ga₁₋ₓInₓN_{y}As_{1-y-z}Sb_{z} is not a simple function of composition. The composition that yields a desired band gap with a specific lattice constant can be found by empirically varying the composition. However, the quality of the Ga₁₋ₓInₓN_{y}As_{1-y-z}Sb_{z} alloy as reflected in attributes such as the Jsc, Voc, FF, and efficiency can also depend on processing and annealing conditions and parameters. High efficiency multijunction photovoltaic cells comprising dilute nitrides are disclosed, for example, in U.S. Pat. No. 8,912,433 and U.S. Application Publication No. 2017/0110613, each of which is incorporated by reference in its entirety. High efficiency GaInNAsBi and GaInNAsSbBi junctions are disclosed in U.S. Application Publication No. 2017/036572, which is incorporated by reference in its entirety.

Dilute nitride sub-cells having graded doping profiles are disclosed in U.S. Pat. No. 9,214,580, U.S. Application Publication No. 2016/9118526, and U.S. Application Publication No. 2017/0338357, each of which is incorporated by reference in its entirety. Graded doping profiles have been shown to improve the performance of the dilute nitride junctions. Such junctions can comprise an unintentionally doped dilute nitride region, having a first thickness and having an unintentional doping concentration less than about 1×10¹⁵/cm³, and a doped dilute nitride region having a second thickness and a dopant concentration between 1×10¹⁵/cm³ and 1×10¹⁹/cm³, wherein the first thickness is between 0.3 μm and 1.5 μm, and the second thickness is between 1 μm and 2 μm, and wherein the first thickness is less than the second thickness.

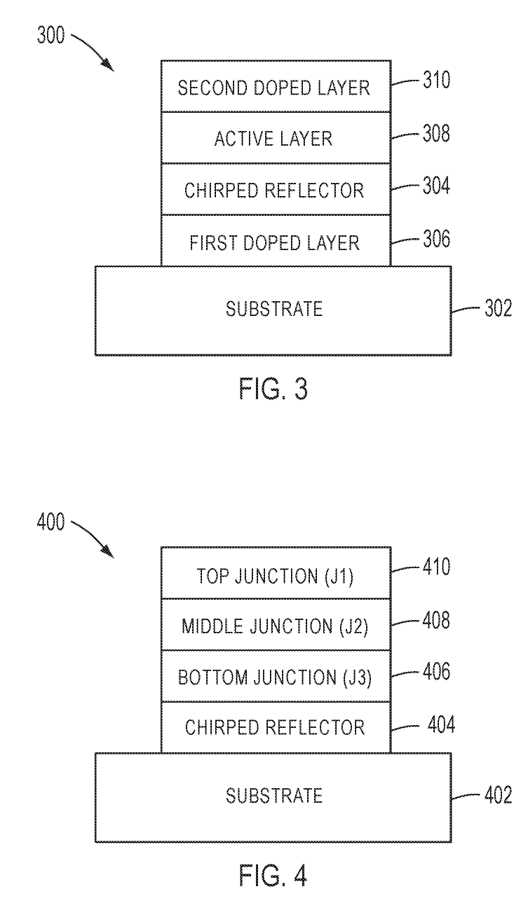

FIG. 3 shows a side view of an example of a semiconductor optoelectronic absorption device 300 according to the present disclosure. Device 300 comprises a substrate 302, a first semiconductor layer 306, a chirped reflector 304, an absorption layer 308, and a second semiconductor layer 310. For simplicity, each layer is shown as a single layer. However, it will be understood that each layer can include one or more layers with differing compositions, thicknesses and doping levels in order to provide the appropriate optical and/or electrical functionality, and to improve interface quality, electron transport, hole transport and/or other optoelectronic properties.

Substrate 302 can have a lattice constant that matches or nearly matches the lattice constant of GaAs or Ge. The substrate can be GaAs. Substrate 302 may be doped p-type, or n-type, or may be a semi-insulating (SI substrate). The thickness of substrate 302 can be chosen to be any suitable thickness. Substrate 302 can include one or more layers, for example a Si layer having an overlying SiGeSn buffer layer that is engineered to have a lattice constant that matches or nearly matches the lattice constant of GaAs or Ge. This can mean the substrate can have a lattice parameter different than that of GaAs or Ge by less than or equal to 3%, less than or equal 1%, or less than or equal 0.5%.

First doped layer 306 can have a doping of one type and the second doped layer 310 has a doping of the opposite type. If first doped layer 306 is doped n-type, the second doped layer 310 is doped p-type. Conversely, if first doped layer 306 is doped p-type, the second doped layer 310 is doped n-type. Examples of p-type dopants include C and Be. Examples of n-type dopants include Si and Te. Doped layers 306 and 310 are chosen to have a composition that is lattice matched or pseudomorphically strained to the substrate. The doped layers can comprise any III-V material, such as GaAs, AlGaAs, GaInAs, GaInP, GaInPAs, GaInNAs, GaInNAsSb. The bandgap of the first and second doped layers can be higher than the bandgap of active region 308. Doping levels between about 1×10¹⁵ cm⁻³ and 2×10¹⁹ cm⁻³ may be used. Doping levels may be constant within a layer, or the doping profile may be graded, for example, increasing the doping level from a minimum value to a maximum value as a function of the distance from the interface between the doped layer and the active layer. Doped layers 306 and 310 can have thicknesses between about 50 nm and 3 μm.

Chirped reflector 304 can comprise alternating layers of materials having different refractive indices. The refractive index difference between the layers, and the layer thicknesses provides a reflectivity at a desired wavelength range. Chirped reflector 304 comprises at least two different materials with different refractive indices and at least two different layer thicknesses. The layers of chirped reflector 304 can comprise, for example, semiconductor materials of Groups III and V of the periodic table such as, for example, AlAs, AlGaAs, GaAs, InAs, InGaAs, AlInAs, InGaP, AlInGaP, InGaP, GaP, InP, AlP, AlInP, or AlInGaAs.

Absorption layer 308 is lattice matched or pseudomorphically strained to the substrate and/or the doped layers. The bandgap of absorption layer 308 is less than the bandgap of the doped layers 306 and 310. Absorption layer 308 comprises a layer capable of absorbing over a desired wavelength range.

Absorption layer 308 can include a dilute nitride material. A dilute nitride material is Ga₁₋ₓInₓN_{y}As_{1-y-z}Sb_{z}, where x, y and z fall within the ranges 0≤x≤0.4, 0≤y≤0.1 and 0≤z≤0.2, respectively. In some embodiments, x, y and z can fall within the ranges of 0.01≤x≤0.4, 0.02≤y≤0.07 and 0.001≤z≤0.04, respectively. Absorption layer 308 can have a bandgap from 0.7 eV and 1.2 eV such that light can be absorbed at wavelengths up to about 1.8 μm. Bismuth (Bi) may be added as a surfactant during growth of the dilute nitride, improving material quality (such as defect density), and the device performance. The thickness of absorption layer 308 can be between about 0.2 μm and 10 μm. The thickness of absorption layer 308 can be between about 1 μm and 4 μm. Absorption layer 308 can be compressively strained with respect to the substrate 302. Strain can also improve device performance. For a photodetector, the device performance of most relevance includes the dark current, operating speed, noise, and responsivity.

Chirped reflector 304 overlies substrate layer 302 and first doped layer 306 and underlies absorption layer 308. Chirped reflector 304 is lattice matched or pseudomorphically strained to the substrate and other overlying and underlying layers. Chirped reflector 304 can be designed to have a reflection spectrum that reflects light at wavelengths that can be absorbed by absorbing region 308. Light that is not initially absorbed in absorption layer 308 during a first pass through the absorption layer 308 can be reflected back into absorption layer 308 so that it can be absorbed.

Chirped reflector 304 can be doped, with the same doping type as first doped layer 306.

Absorbing region 308 and doped layers 306 and 310 form a p-i-n or an n-i-p junction. This junction provides the basic structure for operation of a device such as a photodetector or a light-emitting diode. For photodetectors, p-i-n epitaxial structures have stringent requirements on the background doping in the intrinsic region (active region) of the devices which are typically operated at zero or very low bias. Therefore, the active region is not deliberately doped. The active layer can be an intrinsic layer or an unintentionally doped layer. Unintentionally doped semiconductors do not have dopants intentionally added but can include a nonzero concentration of impurities that act as dopants. For example, the carrier concentration of an active region can be, for example, less than 1×10¹⁶ cm⁻³ (measured at 25° C.), less than 5×10¹⁵ cm⁻³, or less than approximately 1×10¹⁵ cm⁻³.

FIG. 4 shows a schematic cross-section of a three-junction (3J) multijunction photovoltaic cell 400. With GaAs as an example of a substrate 402, semiconductor materials can be deposited on the substrate 402 to form a chirped reflector 404. A first junction 406 can then formed. The first junction 406 can a dilute nitride junction. In this example, two further junctions (408 and 410) are included in the structure, with all junctions electrically connected by tunnel junctions (not shown), providing series connection of the multiple p-n junctions.

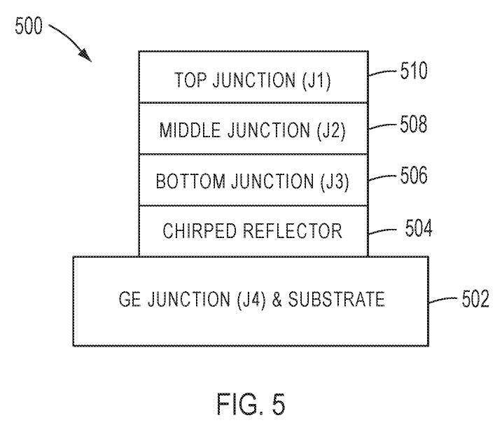

FIG. 5 shows a schematic cross-section of a four-junction (4J) multijunction photovoltaic cell 500. With Ge as an example of a substrate 502, the Ge layer(s) can form a bottom junction, having a p-n junction. A chirped reflector 504 can then formed over the substrate, followed by junction 506. In this example, junction 506 can be a dilute nitride junction. In this example, two further junctions (508 and 510) can be included in the structure, with all junctions interconnected by tunnel junctions (not shown), providing series connection of the multiple p-n junctions.

A practitioner skilled in the art understands that other types of layers may be incorporated or omitted in multijunction photovoltaic cells 400 and 500 to create a functional device and therefore are not described in detail. These other types of layers include, for example, coverglass, anti-reflection coating (ARC), contact layers, front surface field (FSF), tunnel junctions, window, emitter, back surface field (BSF), nucleation layers, buffer layers, and a substrate or wafer handle. In each of the embodiments described and illustrated herein, additional semiconductor layers can be present to create a multijunction photovoltaic cell. Specifically, cap or contact layer(s), ARC layers and electrical contacts (also denoted as the metal grid) can be formed above the top junction, and buffer layer(s), the substrate or handle, and bottom contacts can be formed or be present below the bottom junction. In certain embodiments, the substrate may also function as the bottom junction, such as in a germanium junction. Multijunction photovoltaic cells may also be formed without one or more of the layers listed above, as known to those skilled in the art. Each of these layers requires careful design to ensure that its incorporation into a multijunction photovoltaic cell does not compromise high performance

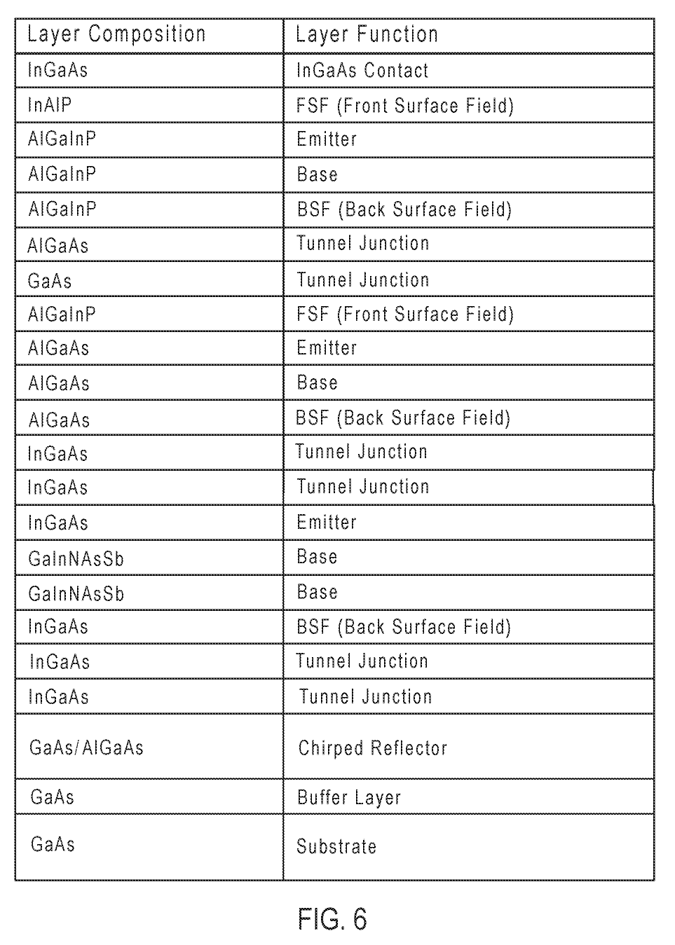

FIG. 6 shows an example of a 3J structure (e.g., AlInGaP/(Al,In)GaAs/GaInNAsSb), illustrating possible additional semiconductor layers that may be present in multijunction photovoltaic cell 400. In this structure, a chirped reflector overlies a buffer layer that is deposited on a substrate. In some embodiments, a chirped reflector can also act as the buffer layer. The chirped reflector is shown comprising GaAs/AlGaAs layers. The chirped reflector comprises at least two different materials with different refractive indices and at least two different layer thicknesses. Chirped reflector 304 can comprise, for example, semiconductor materials of Groups III and V of the periodic table such as, for example, AlAs, AlGaAs, GaAs, InAs, InGaAs, AlInAs, InGaP, AlInGaP, InGaP, GaP, InP, AlP, AlInP, or AlInGaAs. In this example, the chirped reflector underlies a tunnel junction, a two-layer structure that includes a high n-doped layer and a high p-doped layer, as is known in the art, and underlies a dilute nitride absorber. The dilute nitride absorber may have single layer or may have more than one layer. Examples of dilute nitride absorbers having two layers, each layer having a different doping profile, are described in U.S. Patent Application No. 2016/0118526 and in U.S. Patent Application No. 2017/0338357, both of which are incorporated herein by reference.

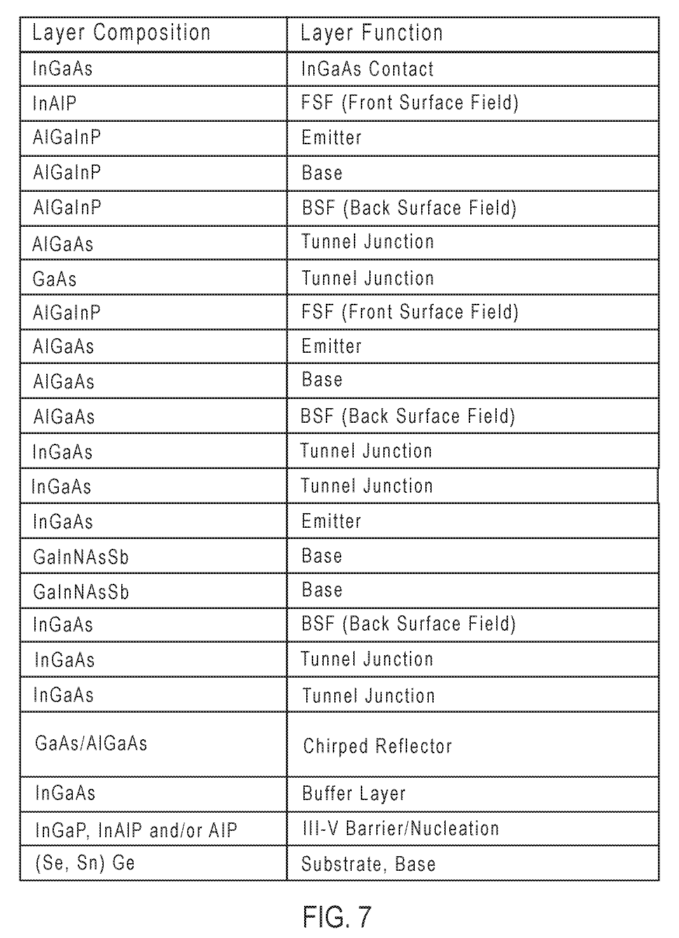

FIG. 7 shows an example of a 4J structure (e.g., AlInGaP/(Al,In)GaAs/GaInNAsSb/Ge) with a high temperature barrier and nucleation layer comprising InAlPSb, illustrating these possible additional semiconductor layers that may be present in multijunction photovoltaic cell 500 (FIG. 5). In this structure, a chirped reflector overlies a buffer layer that is deposited on a substrate. In some embodiments, the chirped reflector can also act as the buffer layer. The chirped reflector is shown comprising GaAs/AlGaAs layers. The chirped reflector comprises at least two different materials with different refractive indices and at least two different layer thicknesses. Chirped reflector 504 (FIG. 5) can comprise, for example, semiconductor materials of Groups III and V of the periodic table such as, for example, AlAs, AlGaAs, GaAs, InAs, InGaAs, AlInAs, InGaP, AlInGaP, InGaP, GaP, InP, AlP, AlInP, or AlInGaAs. Similar to the example in the preceding example, in this example, the chirped reflector underlies a tunnel junction, a two-layer structure that includes a high n-doped layer and a high p-doped layer, as is known in the art, and underlies a dilute nitride absorber. The dilute nitride absorber may have single layer or may have more than one layer. Examples of dilute nitride absorbers having two layers, each layer having a different doping profile, are described in U.S. Patent Application No. 2016/0118526 and U.S. Patent Application No. 2017/0338357, both of which are incorporated herein by reference.

A DBR is a periodic structure formed from alternating semiconductor materials with different refractive indices that can be used to achieve high reflection within a range of frequencies or wavelengths. Two such layers of a mirror structure may be referred to as a mirror pair. In a non-chirped DBR design, the thicknesses of each of the layers are chosen to be an integer multiple of a quarter wavelength, based on a desired design wavelength λ₀, to optimize reflection at the particular wavelength. That is, the thickness of each layer is chosen to be an integer multiple of λ₀/4n, where n is the refractive index of the material at wavelength λ₀. In a non-chirped DBR, all mirror layers are chosen to have these thicknesses, thus the DBR has a regular periodic structure associated with the thickness of the mirror pairs. In some embodiments, the interface between adjacent layers of the DBR may be compositionally stepped, but the structural periodicity is constant throughout. A DBR can comprise, for example semiconductor materials of Groups III and V of the periodic table such as, for example, AlAs, AlGaAs, GaAs, InAs, GaInAs, AlInAs, InGaP, AlInGaP, InGaP, GaP, InP, AlP, AlInP, or AlInGaAs. A DBR can comprise a dielectric material. The number, order, and thickness of each the layers forming a DBR can be selected in such a way that a desired wavelength range of an incident solar spectrum is reflected by the DBR into the junction(s) overlying the DBR. In designs using a DBR, the thickness of the overlying junction can be reduced by using a DBR without reducing light absorption in the overlying junction. At the same time, the DBR interlayers can be selected such that the DBR transmits higher wavelength light to be absorbed by the junctions underlying the DBR. This ensures that current generation in the underlying junctions is not reduced by the DBR. Electrical properties of the DBR can be tuned by doping the DBR interlayers with Si, Te, Zn, C, Mg, and/or Se.

DBRs are a mature technology in the field of GaAs VCSELs (Vertical Cavity Surface Emitting Lasers), where two DBRs cladding a quantum-well active region produce an out of plane Fabry-Perot lasing cavity. GaAs VCSELs use materials present in typical photovoltaic cells, such as GaAs and AlGaAs. An estimate shows that a DBR constructed of from 15 to 20 alternating pairs of 80 nm- to 90 nm-thick GaAs and 90 nm- to 100 nm-thick Al_{0.75}Ga_{0.25}As interlayers can achieve 90% to 97% reflectivity at wavelengths within a range from 950 nm to 1,100 nm.

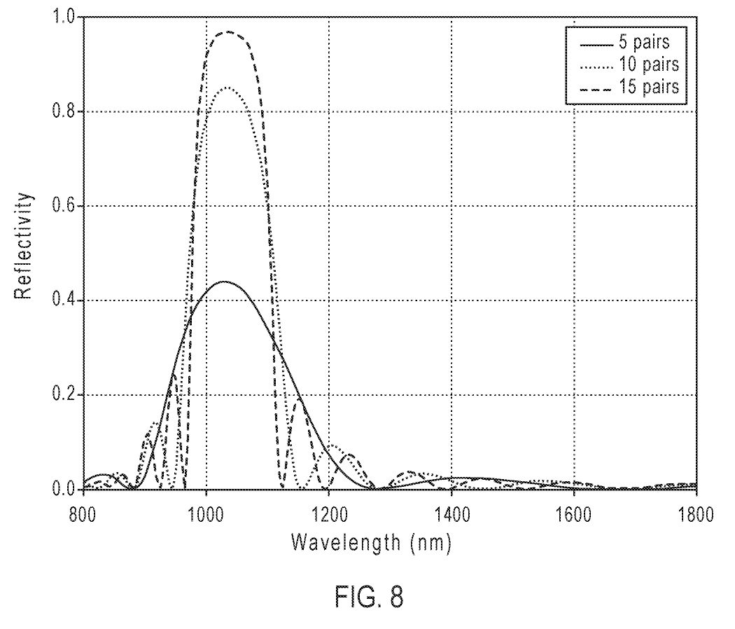

FIG. 8 shows calculated spectral reflectivity of non-chirped DBRs having five (5) periodic structures, where each periodic structure comprises a pair of GaAs/AlGaAs interlayers, ten (10) periodic structures, and fifteen (15) periodic structures. The DBRs were designed for a normal maximum reflectivity at 1.05 μm (1,050 nm). The thickness of each of the interlayers was between 70 nm and 90 nm. The normal reflectivity of a DBR increases with increasing number of periodic structures. Both the peak reflectivity and the stop-bandwidth (i.e., full-width-half-maximum) increase with increasing number of periodic structures. The effect is highly non-linear, as shown in FIG. 5, and quickly maximizes close to 100% reflectivity. Side-band reflectivity (i.e., reflectivity at wavelengths greater than 1,050 nm) results in some loss for absorption by an underlying layer such as a (Si,Sn)Ge junction. The DBR having fifteen (15) GaAs/AlGaAs pairs has a full-width-half-maximum (FWHM) of about 130 nm.

A DBR stack can be grown by either molecular beam epitaxy (MBE) or by metal-organic chemical vapor deposition (MOCVD). Optimized high doping can reduce electrical resistance (a well-understood process in VCSEL technology) and can maintain optical transparency for light absorbed by an underlying (Si,Sn)Ge junction in a photovoltaic cell. The interfaces between adjacent layers may be delta doped, for example. An interface layer may also have a graded composition over a thin thickness, transitioning from the composition of one layer to the composition of the adjacent layer. The composition grading can be achieved using thin layers, such as layers having a thickness from 0.5 nm to 3 nm, or from 1 nm or 2 nm. For example, an interface between a GaAs and an AlAs layer can be graded using thin layers of Al_{0.2}Ga_{0.8}As, A_{0.5}Ga_{0.5}As an Al_{0.8}Ga_{0.2}As. Use of a graded interface layer between DBR interlayers can benefit electrical performance of the DBR, without adversely affecting the optical properties.

A DBR can be situated below or above a tunnel junction. When situated below a tunnel junction, the DBR can be n-type and when situated above a tunnel junction a DBR can be p-type.

The absorption spectrum for a junction such as a dilute nitride junction can be between 300 nm and 400 nm wide. Non-chirped DBRs designed to optimize reflectivity at a single wavelength are inadequate for providing high reflectivity over the entire absorption range of a junction of a multijunction photovoltaic cell. Furthermore, the reflectivity spectrum magnitude and position depend on the angle of incident light. This can reduce the effectiveness of a DBR used in multijunction photovoltaic devices which optimally collect light over a wide range of incident angles.

To increase the reflectivity spectrum of a DBR for use in multijunction photovoltaic devices, a chirped reflector, or chirped DBR (CDBR) can be used.

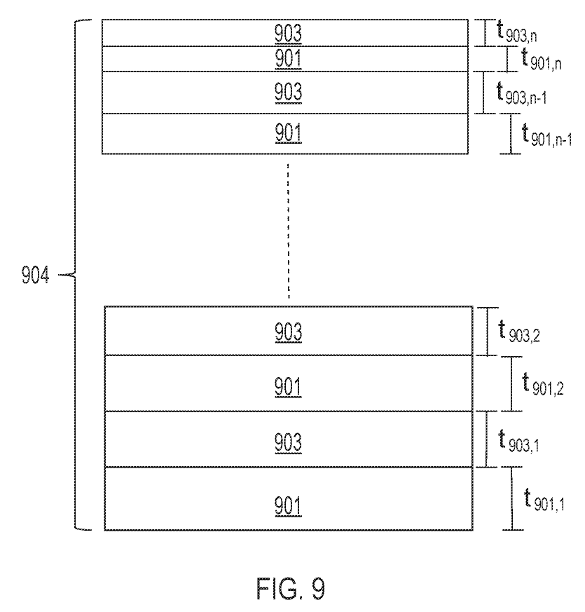

FIG. 9 illustrates an example of a design of a chirped reflector. The chirped reflector 904 can comprise two lattice-matched or pseudomorphic materials with differing refractive index. Chirped reflector 904 can comprise alternating layers of a first CDBR interlayer 901 and a second CDBR interlayer 903, in which first CDBR interlayer 901 comprises a first composition and a first refractive index and second CDBR interlayer 903 comprises a second composition and second refractive index. An adjacent first CDBR interlayer 901 and an adjacent second CDBR interlayer 903 provide a second mirror pair. A mirror pair can comprise a first CDBR interlayer comprising GaAs and a second CDBR interlayer comprising AlGaAs. Referring to FIG. 9, the top two CDBR interlayers 903/901 form a first mirror pair, and the next two CDBR interlayers form a second mirror pair. A mirror pair can comprise a first interlayer comprising AlₓGa₁₋ₓAs and a second interlayer comprising Al_{y}Ga_{1-y}As, where 0≤x≤1, and 0≤y≤1, and the values of x and y are different.

A CDBR can comprise two or more mirror pairs. A CDBR can comprise, for example, from 5 to 30 mirror pairs, or from 5 to 20 mirror pairs. The first mirror pair can have corresponding thicknesses t_{901,1} and t_{903,1}. The second mirror pair can have corresponding thicknesses t_{901,2} and t_{903,1}. The n^{th} mirror pair can have corresponding thicknesses t_{901,n} and t_{903,n}. The optical thickness of alternating layers 901 and 903 can monotonically vary. FIG. 9 shows the optical thickness of the layers decreasing monotonically from the first mirror pair to the n^{th} mirror pair. The optical thickness of the CDBR interlayers can increase monotonically.

Whereas for a non-chirped DBR, the layer thicknesses are chosen to be λ₀/4n to optimize reflection at a specific design wavelength, in the CDBR the thickest layers are chosen to have a thickness of (1+C) λ₀/4n and the thinnest layers have a thickness of (1−C) λ₀/4n, where C is the chirp fraction. For example, if the design wavelength can be 1 μm and the chirp fraction can be 0.15, for a center wavelength of 1,000 nm, mirror pairs are designed over a range of wavelengths between 850 nm and 1,150 nm. The thickness of an interlayer can be modified slightly to account for the refractive index at a given wavelength for which a particular interlayer is being designed. The chirp fraction can be expressed in terms of the thickness of a mirror pair.

For use in multijunction photovoltaic devices, a CDBR can underlie a dilute nitride layer, and the interlayers can have thickness from 50 nm to 110 nm, and the mirror pairs can have a thickness from 100 nm and 210 nm. A CDBR can be designed to have a reflection maximum at a wavelength within a range, for example, from 900 nm to 1,200 nm, or within a range from 950 nm to 1,100 nm. For use in a photodetector, a CDBR can have interlayer thicknesses from 50 nm and 160 nm, and a reflection maximum at a wavelength within a range from 900 nm to 1,700 nm.

A CDBR can have a linear chirp (described above), or the chirp can be non-linear. A CDBR can have a weighted chirp, such that at least two mirror pairs can be used with the same design thickness, in order to reinforce reflection at a desired wavelength range within the desired high-reflectivity region of the CDBR. Additional mirror pairs may be introduced at wavelengths within the reflectivity spectrum where a local reflectivity minimum occurs. In some examples, the chirp fraction can have a value between 1% and 30%. In some examples, the chirp fraction can be within a range from 10% to 25%, or within a range from 15% to 25%.

The interfaces between adjacent layers in a CDBR may be delta doped. The interfaces of a CDBR may have a graded composition over a thin thickness, transitioning from the composition of one layer to the composition of the adjacent layer. An interlayer can comprise sub-layers, with different elemental composition, different doping level and/or different refractive index, without degrading the optical performance of the CDBR.

A CDBR can comprise a periodically repeating structure comprising, for example, from two to six layers such as two layers (mirror pair), three layers, four layers, five layers, or six layers. Each of the layers forming a periodically repeating structure can have a different elemental composition and/or a different refractive index, with only the layer thicknesses varying between adjacent repeating structures.

The peak reflectivity of a CDBR, can be adjusted by selecting the materials and thicknesses of the interlayers forming the CDBR periodic structures. For a dilute nitride such as GaInNAsSb, GaInNAsBi, and GaInNAsSbBi suitable for use in photovoltaic cells, depending on the band gap of the material, the normal peak reflectivity of the CDBR can be at a wavelength within a range, for example, from 900 nm (1.378 eV) to 1,400 nm (0.885 eV), from 900 nm (1378 eV) to 1,300 nm (0.954 eV), from 900 nm (1.378 eV) to 1,200 nm (1.033 eV), or from 900 nm (1378 eV) to 1,100 nm (1.127 eV). For a dilute nitride such as GaInNAsSb, GaInNAsBi, and GaInNAsSbBi suitable for use in photovoltaic cells, depending on the band gap of the material, the normal peak reflectivity of the DBR can be within a range, for example, from 1,000 nm to 1,200 nm, from 1,050 nm to 1,150 nm, or from 1,050 nm to 1,100 nm; and the normal peak reflectivity of the CDBR can be at a wavelength at least 50 nm less than, at least 75 nm less than, at least 100 nm less than, at least 125 nm less than, or at least 150 nm less than the absorption edge of the underlying layer, such as an underlying (Sn,Si)Ge layer. For a dilute nitride such as GaInNAsSb, GaInNAsBi, and GaInNAsSbBi suitable for use in photovoltaic cells, depending on the band gap of the material, the normal peak reflectivity of the CDBR can be within a range, for example, from 900 nm to 1,200 nm, from 950 nm to 1,150 nm, or from 1,000 nm to 1,100 nm.

The FWHM of the CDBR can be, for example, greater than 100 nm, or greater than 200 nm or greater than 300 nm, and the long wavelength FWHM value of the CDBR can be at a wavelength within a range from 25 nm to 150 nm, from 25 nm to 125 nm, from 25 nm to 100 nm from 25 nm to 75 nm, from 50 nm to 150 nm, from 50 nm to 125 nm, from 50 nm to 100 nm, from 50 nm to 75 nm less than the short wavelength absorption edge of an underlying layer such as an underlying light absorbing layer, such as an underlying (Sn,Si)Ge layer, or can be within 50 nm of the long wavelength absorption edge of an overlying light absorbing region such dilute nitride layer. The long wavelength absorption edge of a Ge layer can be about 1800 nm.

For a dilute nitride such as GaInNAsSb, GaInNAsBi, and GaInNAsSbBi suitable for use in photodetectors at a variety of short wavelength infrared wavelengths, depending on the composition and band gap of the material, the normal peak reflectivity of the CDBR can be at a wavelength within a range, for example, from 900 nm (1.378 eV) to 1,700 nm (0.729 eV)

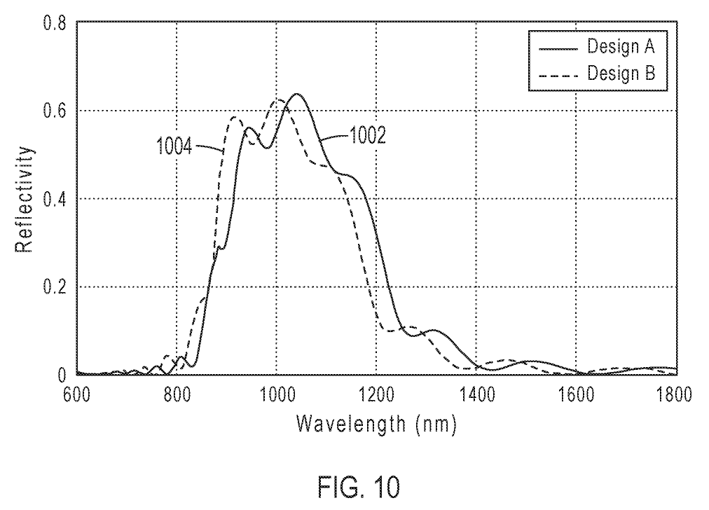

The reflectivity of the CDBR can be greater than 30%, or greater than 50% or greater than 70%, or greater than 90% across a wavelength range defined by the full-width half-maximum (FWHM) of the CDBR reflectivity spectrum. The FWHM range is defined as the wavelength on either side of the peak reflectivity value for which the reflectivity of the spectrum is at least 50% of the peak reflectivity value. For example, if the peak reflectivity of the reflectivity spectrum is 60%, the FWHM is defined by the wavelength range at which the reflectivity value falls to 30%. If the peak reflectivity value is 90%, the FWHM is defined by the wavelength range at which the reflectivity value falls to 45%. For example, referring to FIG. 10, CDBR design A has a FWHM of about 300 nm, which extends from the low wavelength cutoff of about 900 nm to the high wavelength cutoff of about 1200 nm.

FIG. 10 shows the modeled reflectivity spectra for two CDBRs at normal incidence. Design A was designed to have a peak reflectivity at approximately 1,040 nm, and design B was designed to have a peak reflectivity at approximately 1,000 nm. The chirp factor for both designs was 0.18. Each design included 10 pairs of GaAs/AlAs mirrors. The mirror layer thicknesses for the first mirror pair in design A was 60 nm and 73 nm, for the GaAs and AlAs layers, respectively, and the thicknesses for the tenth mirror pair was 89 nm and 102 nm, for the GaAs and AlAs layers, respectively. The mirror layer thicknesses for the first mirror pair in design B was 57 nm and 70 nm for the GaAs and AlAs layers, respectively, and the thicknesses for the tenth mirror pair was 86 nm and 99 nm for the GaAs and AlAs layers, respectively. For a chirp factor of 0.18, the thickness change between adjacent pairs of mirrors is approximately 6.4 nm (or 3.2 nm per interlayer). Curve 1002 shows the calculated reflectivity spectrum for design A, and curve 1004 shows the calculated reflectivity spectrum for design B. The peak reflectivity for design A occurs at 1,041 nm, and the full-width half maximum (FWHM) of the reflectivity spectrum is 300 nm. The peak reflectivity for design B occurs at 1,005 nm, and the FWHM of the reflectivity spectrum was 285 nm. The peak reflectivity for both design A and design B was 64%, in comparison with 85% for the ten-period DBR designed with a peak reflectivity at 1,040 nm, shown in FIG. 8. While, the peak reflectivity for the CDBRs has decreased, the FWHM is considerably broader, covering all, or the majority of, the absorption spectrum for a dilute nitride junction within a multijunction photovoltaic cell. The ability to provide reflectivity across a larger portion of the absorption spectrum of the overlying junction is important, as it can increase the spectral responsivity of a device such as a photodetector or the absorption in a junction of a photovoltaic cell across a broader wavelength range. Increasing the number of mirror pairs can increase the reflectivity.

Integration of a CDBR into a multijunction photovoltaic cell is especially advantageous when the overlying junction comprises a material with a low diffusion length, or when the minority carrier diffusion length of the junction substantially deteriorates during its operational lifetime. Device deterioration is unavoidable in photovoltaic cells that are deployed into space and exposed to highly energetic particles. Radiation damage causes the diffusion length in a junction to decrease such that only a portion of the generated minority carriers reach the depletion layer. Consequently, such deterioration can decrease the operational capabilities and lifetime of a spacecraft powered by dilute nitride-containing multijunction photovoltaic cells. With a CDBR, the thickness of an overlying dilute nitride junction can be reduced without compromising optical absorption in the dilute nitride junction. The CDBR effectively decouples the effects of the optical thickness from the physical thickness. The combination of introducing a CDBR and simultaneously reducing the dilute nitride junction thickness has a positive effect on current generation. A more advantageous current generation profile throughout the depth of the active layer of a dilute nitride junction can be achieved. It is particularly significant that the average distance of the generated minority carriers to the depletion layer is significantly reduced due to the reduced dilute nitride junction thickness. This leads to an increased probability that the minority carriers will encounter the depletion layer during diffusion and will thus contribute to the current collected at the contacts. By using an underlying CDBR, a thinner dilute nitride third junction (J3) in a 4J photovoltaic cell can be used and thereby improve carrier collection under beginning-of-life (BOL) and end-of-life (EOL) conditions due to reduced diffusion length for carrier collection.

A CDBR layer provided by the present disclosure can be designed to improve the performance of an overlying dilute nitride layer such as a dilute nitride junction thereby improving the performance of a device such as a multijunction photovoltaic cell comprising a dilute nitride layer and an underlying CDBR layer. A CDBR layer provided by the present disclosure can be designed (1) to reflect light capable of being absorbed by the dilute nitride junction back into the overlying dilute nitride junction; and (2) to transmit light at wavelengths that can be absorbed by an underlying junction.

A CDBR layer provided by the present disclosure can be designed to reduce the thickness of an overlying dilute nitride layer such as a dilute nitride junction, allowing improved carrier collection thereby improving the performance of a device such as a multijunction photovoltaic cell comprising the dilute nitride junction and underlying CDBR layer, as will be described later.

Several structures were simulated for comparison purposes to assess the impact of a CDBR on performance of junctions in a photovoltaic cell. A baseline 4J structure with a dilute nitride (J3) thickness of 2.5 μm was simulated. A 4J structure with a thinner (1.5 mm thick) dilute nitride absorbing region was then simulated with and without a CDBR between J3 and J4 (Ge). The CDBR was designed using 21 GaAs/AlAs mirror pairs to have a peak wavelength of 950 nm, and a linear chirp profile with a chirp factor of 17%. The mirror layer thicknesses for the first mirror pair in this design were approximately 54 nm and 66 nm for the GaAs and AlAs layers, respectively, and the thicknesses for the last mirror pair were approximately 79 nm and 93 nm for the GaAs and AlAs layers, respectively, and the total thickness of the CDBR was about 3.07 μm.

Table 1 shows the calculated J3 and J4 current densities of a 4J photovoltaic cell illuminated with an AM0 source at normal incidence.

TABLE 1
Calculated J3 and J4 current densities for a
4J photovoltaic cell for an AM0 source.

| | J3 | J3 current | J4 current |
|---|---|---|---|
| | thickness | density | density |
| DBR type | (μm) | (mA/cm²) | (mA/cm²) |
| None | 2.5 | 15.7 | 20.4 |
| None | 1.5 | 13.5 | 22.5 |
| CDBR, 21 pair, λ₀ = 950 nm, | 1.5 | 15.4 | 19.1 |
| 17% chirp, linear | | | |

The short circuit current densities for the top cell (J1), and the second cell (J2) were calculated to be 15.6 mA/cm² and 15.1 mA/cm², respectively, making J2 the current-limiting cell. Thinning the J3 junction from 2.5 μm to 1.5 μm reduced the current density of the J3 junction by 14%, making it the current limiting cell, while the short circuit current of the J4 junction increased by 10%. The CDBR restored the J3 current to near its previous value for the baseline design, while reducing the J4 short circuit current of the J4 junction by 6% compared to the baseline design. However, because the J4 junction has excess current, this loss can be tolerated without degrading the overall performance of the multijunction cell.

FIG. 11 shows the simulated wavelength-dependent absorptance (defined as the difference between the net incident flux and the net exit flux for a layer or group of layers) for the J3 junction (dilute nitride) and junction J4 (Ge) of a 4J photovoltaic cell with and without a CDBR between the dilute nitride J3 junction and the Ge J4 junction. The thickness of the J3 junction was 1.5 μm. It can be seen that the absorptance for J3 in the design with the CDBR is greater than for the design without the CDBR for all wavelengths in the range from 850 nm to 1,150 nm corresponding to the absorption spectrum of the J3 dilute nitride junction, confirming the CDBR reflects across a wider portion of the absorption spectrum of the dilute nitride junction. Without the CDBR, the effect of thinning J3 results in a broader absorptance spectrum for J4, for light at wavelengths that are not well absorbed by the thinner J3, but this short wavelength tail for J4 is eliminated by the CDBR. As shown in FIG. 11, the absorptance of the J3 junction with an underlying CDBR is greater than that for a similar J3 junction without a CDBR is greater throughout the entire J3 absorption spectrum from about 825 nm to about 1150 nm. The absorptance of the J3 junction is increased throughout the entire absorption spectrum of the J3 junction from the low wavelength absorption edge at about 850 nm to the high wavelength absorption edge at about 1150 nm.

The difference in J3 absorptance with wavelength between the two designs is shown in FIG. 12. It can be seen that the CDBR has increased absorptance across the wavelength range between approximately 850 nm and 1,150 nm. A non-chirped DBR has a narrower reflectivity FWHM, and so could only increase absorptance over a portion of this wavelength range.

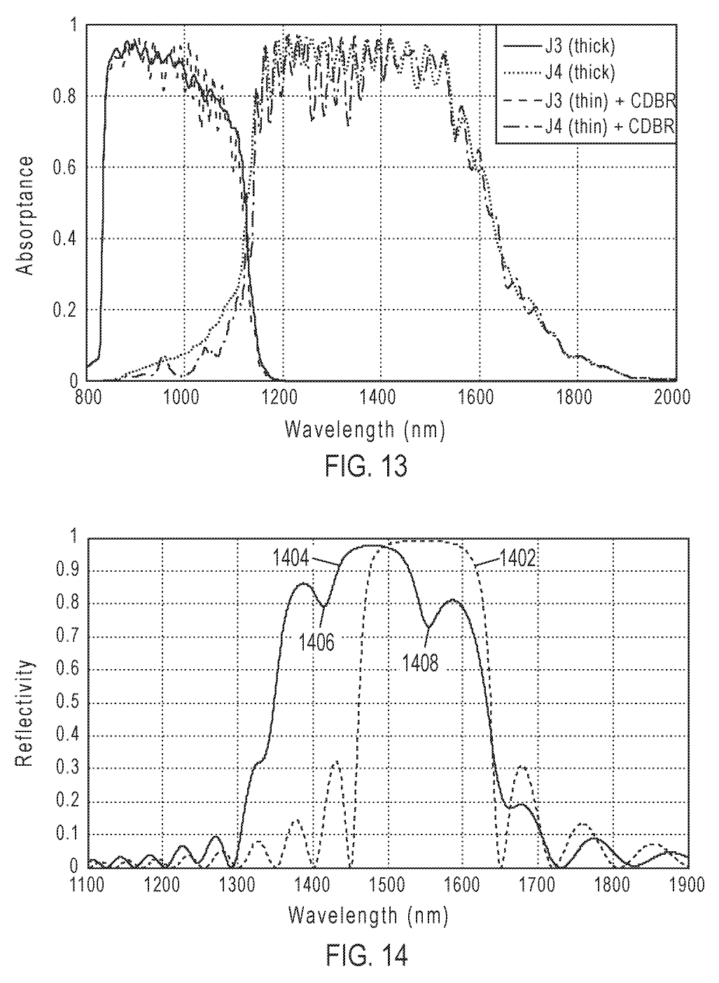

The wavelength-dependent efficiency of J3 and J4 in the design with the CDBR was compared to the performance of the baseline structure with a 2.5 μm thick dilute nitride layer. The comparison is shown in FIG. 13. It can be seen that the absorptance of the baseline structure and the thinner (1.5 μm thick) J3 structure with a CDBR matches very well for J3, with the CDBR introducing oscillations on either side of the baseline characteristic, and with the short current density matching closely, as indicated in Table 1. The absorptance of the J4 junction is similar to that of the baseline structure, with small variations leading to a 6% decrease in the short circuit current. However, the J4 junction still exhibits excess current with respect to the rest of the junctions.

FIG. 14 shows the modeled reflectivity spectra for a non-chirped DBR and a CDBR at normal incidence. Both designs were configured to have a long-wavelength cut-off of the FWHM of the reflectivity spectrum at an energy of about 0.76 eV, corresponding to a wavelength of about 1,630 nm. The reflectivity spectrum of a non-chirped DBR is shown as curve 1402, while the reflectivity spectrum of the CDBR is shown as curve 1404.

The non-chirped DBR includes 20.5 pairs of GaAs/AlAs mirror layers, with mirror layer thicknesses of approximately 115 nm and 132 nm, for the GaAs and AlAs layers, respectively. The peak reflectivity of just over 99% for reflectivity spectrum 1402 occurs at a wavelength of approximately 1540 nm, and the FWHM of the reflectivity spectrum 1402 is approximately 175 nm. Therefore, the responsivity of an overlying absorber layer for a photodetector may be enhanced over an approximately 175 nm range between wavelengths of about 1460 nm and 1635 nm.

The CDBR includes 20.5 pairs of GaAs/AlAs mirror layers, with a chirp factor of approximately 5%. In this example, several pairs of layers with the same thicknesses were used in groupings, the chirp being applied over the adjacent groupings. The thickest mirror layers had thicknesses of approximately 115 nm and 132 nm for the GaAs, and AlAs layers, respectively. The thinnest mirror layers had thicknesses of approximately 105 nm and 121 nm for the GaAs, and AlAs layers, respectively. For reflectivity spectrum 1404, a peak reflectivity of approximately 98% occurs at a wavelength of approximately 1480 nm, and the FWHM is approximately 285 nm between wavelengths of approximately 1345 nm and 1630 nm. Therefore, the responsivity of an overlying absorber layer for a photodetector may be enhanced over an approximately 285 nm range between wavelengths of about 1345 nm and 1630 nm.

Reflectivity spectrum 1404 can be seen to have two dips 1406 and 1408 within the FWHM. However, it will be understood that these may be compensated for by insertion of additional GaAs and AlAs layers having different thicknesses designed to increase the reflectivity at the wavelengths associated with dips 1405 and 1407. While the maximum reflectivity for spectrum 1404 is less than that for spectrum 1402, the FWHM is increased by approximately 110 nm compared to that of a non-chirped DBR, thereby improving the responsivity of an overlying absorber region for a detector over a greater wavelength range than for a non-chirped DBR.

Two CDBRs may also be used in semiconductor devices such as photovoltaic cells and detectors, such as resonant cavity photodetectors (RCPDs), and in particular, arrays of RCPDs configured to absorb light at a wavelength range exceeding the reflectivity bandwidth of non-chirped DBRs. An RCPD may have a bulk region of dilute nitride material but may also be configured to include at least one quantum well. In such devices, the resonant cavity peak for each detector in an array, which is determined by the cavity length of the detector, can be changed. Such changes can be implemented through techniques including non-uniform growth (for example, by not rotating a substrate during growth), patterned growth, additional processing (such as etching and regrowth) and combinations of such techniques. The semiconductor absorber layer used within the cavity may absorb light at wavelengths shorter than its bandgap, but in some embodiments, the bandgap of the absorber layer may be varied across a wafer, using techniques including non-uniform growth, intermixing and combinations of such techniques.

A dilute nitride layer can comprise a first unintentionally doped (UID) region having a first thickness with an unintentional doping concentration less than about 1×10¹⁵/cm³, and a second p-doped dilute nitride region having a second thickness and a dopant concentration that can vary as a function of position from the UID within a range from 1×10¹⁴/cm³ to 1×10¹⁶/cm³ to within a range from 1×10¹⁷/cm³ to 1×10¹⁹/cm³, where the thickness of the second region is greater than the thickness of the UID. The thickness of the UID region can be 1 μm and the thickness of the p-doped region can be 1.5 μm. As has been described, a CDBR allows the thickness of the dilute nitride junction to be thinned from 2.5 μm to a thickness of 1.5 μm without compromising the performance of the photovoltaic cell.

A CDBR can allow the thickness of a dilute nitride layer to be, for example, from 0.5 μm to 2 μm, from 0.5 μm to 1.5 μm, or from 0.5 μm to 1 μm, such that the dilute nitride junction is not the current limiting junction in a multijunction photovoltaic cell. This thinning can be applied in a proportional manner to the UID region and/or to the doped region. The thinning can be applied in a non-proportional manner, where the reduced thickness of the UID region is thinner that the reduced thickness of the p-doped region. The thinning can be applied preferentially, for example, to the p-doped region, such that the thickness of the UID region is greater than or equal to the thickness of the p-doped region. For example, for a nitride junction thickness of 1.5 μm, the thickness of the UID region can be 1 μm and the thickness of the p-type doped region can be 0.5 μm, with all the thinning applied to the p-doped region, or the thickness of the UID region can be 0.8 μm and the thickness of the p-type doped region can be 0.7 μm. The thickness of the UID region can be, for example, from 0.3 μm to 1.5 μm, from 0.5 μm to 1.2 μm, from 0.5 μm to 1 μm, or from 0.5 μm to 0.8 μm; and the thickness of the p-doped region can be, for example, from 0.1 μm and 1.5 μm, from 0.2 μm to 1.2 μm, from 0.4 μm to 1 μm, or from 0.5 μm to 0.8 μm, where the thickness of the UID region is greater than or equal to the thickness of the p-doped region. Preferentially thinning the p-type region can be beneficial for current collection. Reflectivity by the CDBR allows a thinner p-doped region to be used and allows more light absorption to occur closer to the UID region and its interface with the p-doped region. Greater absorption closer to the junction of the dilute nitride junction results in improved carrier collection efficiency, thereby increasing the short circuit current and increasing the efficiency of the junction.

A CDBR provided by the present disclosure can be designed to allow the bandgap of an overlying dilute nitride layer such as a dilute nitride junction to be adjusted or increased by changing the material composition, for example by reducing the nitrogen content, over at least a portion of the dilute nitride layer. Reducing the nitrogen content can provide improved quality material at the expense of long-wavelength absorption. The material composition can also be adjusted by changing the indium content or by changing the Sb content. The CDBR can compensate for the reduced absorption by reflecting light over a broader wavelength range back into the junction so that it can be absorbed and generate photocurrent.

The bandgap of the dilute nitride can be increased by between 2 meV and 100 meV. The bandgap of the dilute nitride can be increased by between 2 meV and 50 meV. The bandgap of both the UID layer and the p-doped layer can be increased. The bandgap of just the p-doped layer can be increased. In some embodiments, more than one bandgap increase can be implemented, for example, two bandgap increases can be applied to different portions of the p-doped region, wherein the sum of the two bandgap increases is between 2 meV and 100 meV. An increased bandgap can improve the voltage across the junction, with the CDBR ensuring current matching can also be achieved, thereby improving the performance of the dilute nitride junction.

The bandgap increase can be graded across the dilute nitride layer. The bandgap grading can be linear or it can be non-linear, such as a quadratic grade, across the dilute nitride layer or portion of the dilute nitride layer. For example, the UID layer may have no bandgap change, but the bandgap of the p-doped region can vary from zero bandgap increase at the interface with the UID region to a bandgap increase of up to 10 meV or 30 meV or 50 meV or 100 meV at the interface between the p-doped region and the back surface field of the dilute nitride junction. Stepped bandgap structures and graded bandgap structures can improve current collection by providing a field effect across the junction, thereby improving the performance of the dilute nitride junction.

In other embodiments, changes in the thickness of the layers, as described above can be combined with composition (and bandgap) changes, as described above.

Methods of fabricating a semiconductor device such as a dilute nitride-containing multijunction photovoltaic cell provided by the present disclosure can comprise providing a p-type semiconductor; forming a n-type region in the p-type semiconductor by exposing the p-type semiconductor to a gas phase n-type dopant to form a n-p junction; depositing ae barrier layer over the n-type region; depositing an arsenic-containing layer over the barrier layer; and thermally annealing the semiconductor device at a temperature within a range from 600° C. to 900° C. for a duration from 5 seconds to 5 hours. Following the thermal annealing step, the semiconductor device retains the performance attributes as before the thermal treatment.

A plurality of layers can be deposited on a substrate in a first materials deposition chamber. The plurality of layers may include etch stop layers, release layers (i.e., layers designed to release the semiconductor layers from the substrate when a specific process sequence, such as chemical etching, is applied), contact layers such as lateral conduction layers, buffer layers, or other semiconductor layers. In one specific embodiment, the sequence of layers deposited includes buffer layer(s), then release layer(s), and then lateral conduction or contact layer(s). Next the substrate is transferred to a second materials deposition chamber where one or more junctions are deposited on top of the existing semiconductor layers. The substrate may then be transferred to either the first materials deposition chamber or to a third materials deposition chamber for deposition of one or more junctions and then deposition of one or more contact layers. Tunnel junctions are also formed between the junctions.

The movement of the substrate and semiconductor layers from one materials deposition chamber to another is defined as the transfer. For example, a substrate is placed in a first materials deposition chamber, and then the buffer layer(s) and the bottom junction(s) are deposited. Then the substrate and semiconductor layers are transferred to a second materials deposition chamber where the remaining junctions are deposited. The transfer may occur in vacuum, at atmospheric pressure in air or another gaseous environment, or in any environment in between. The transfer may further be between materials deposition chambers in one location, which may or may not be interconnected in some way or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

Dilute nitride junctions can be deposited in a first materials deposition chamber, and the (Al,In)GaP and (Al,In)GaAs junctions can be deposited in a second materials deposition chamber, with tunnel junctions formed between the junctions. A transfer can occur in the middle of the growth of one junction, such that a junction has one or more layers deposited in one materials deposition chamber and one or more layers deposited in a second materials deposition chamber.

Some or all of the layers of a dilute nitride junction and the tunnel junctions can be deposited in one materials deposition chamber by molecular beam epitaxy (MBE), and the remaining layers of the photovoltaic cell are deposited by chemical vapor deposition (CVD) in another materials deposition chamber. For example, a substrate is placed in a first materials deposition chamber and layers that may include nucleation layers, buffer layers, emitter and window layers, contact layers and a tunnel junction are grown on the substrate, followed by one or more dilute nitride junctions. If there is more than one dilute nitride junction, then a tunnel junction is grown between adjacent junctions. One or more tunnel junction layers may be grown, and then the substrate is transferred to a second materials deposition chamber where the remaining photovoltaic cell layers are grown by chemical vapor deposition. In certain embodiments, the chemical vapor deposition system is a MOCVD system. In a related embodiment of the invention, a substrate is placed in a first materials deposition chamber and layers that may include nucleation layers, buffer layers, emitter and window layers, contact layers and a tunnel junction are grown on the substrate by chemical vapor deposition. Subsequently, the top junctions, two or more, are grown on the existing semiconductor layers, with tunnel junctions grown between the junctions. Part of the topmost dilute nitride junction, such as the window layer, may then be grown. The substrate is then transferred to a second materials deposition chamber where the remaining semiconductor layers of the topmost dilute nitride junction may be deposited, followed by up to three more dilute nitride junctions, with tunnel junctions between them.

In some embodiments, a surfactant, such as Sb or Bi, may be used when depositing any of the layers of the device. A small fraction of the surfactant may also incorporate within a layer.

A photovoltaic cell can be subjected to one or more thermal annealing treatments after growth. For example, a thermal annealing treatment includes the application of a temperature of 400° C. to 1,000° C. for between 10 microseconds and 10 hours. Thermal annealing may be performed in an atmosphere that includes air, nitrogen, arsenic, arsine, phosphorus, phosphine, hydrogen, forming gas, oxygen, helium and any combination of the preceding materials. A stack of junctions and associated tunnel junctions may be annealed prior to fabrication of additional junctions.

Doping introduces an electric field in addition to the built-in electric field at the emitter-base junction of a junction. The minority carriers generated by the photovoltaic effect in the junction structure are affected by this additional electric field, influencing current collection. Positioning of a doping profile across a dilute nitride base layer can be designed to generate an additional electric field that pushes minority carries to the front of the junction, resulting in a high recombination velocity and substantial improvement in minority carrier collection. Dilute nitride junctions with improved performance characteristics can have graded doping, where the dopant concentration changes with the vertical axis of a junction. The doping profile may not be constant, but may be linear, exponential or have other dependence on position, causing different effects on the electric field. When dilute nitride junctions with graded doping are compared to conventional photovoltaic junctions with a wide, uniform region of intrinsic doping (i.e., undoped), for enhanced carrier collection (an accepted best practice for work with conventional semiconductor materials), graded doping dilute nitride junctions, and in particular exponentially doped dilute nitride junctions, exhibit superior performance characteristics. Position dependent-doping can also be applied to the emitter, further increasing current collection for the junction when used in conjunction with doping of the dilute nitride base.

Although the focus of this disclosure has been on linearly chirped reflectors for multi-junction photovoltaic cells, chirped reflectors may also be used for other light absorption devices, such as photodetectors, and may also be used with other semiconductor materials, including but not limited to InGaAs and GaAsSb.

### ASPECTS OF THE INVENTION

The invention is further defined by the following aspects.

Aspect 1. A chirped distributed Bragg reflector, wherein the chirped distributed Bragg reflector is configured to provide: a reflectivity greater than 50% at an incident angle within a range of ±45 degrees from normal and having a full-width-half-maximum greater than 100 nm; and a transmissibility greater than 80% at a wavelength that is 50 nm higher than the high end of the wavelength range.

Aspect 2. A semiconductor structure comprising: a chirped distributed Bragg reflector; and a light absorbing region overlying the chirped distributed Bragg reflector.

Aspect 3. The semiconductor structure of any one of aspects 2 to 3, wherein, the light absorbing region is configured to absorb light throughout a wavelength range of greater than 100 nm; and the chirped distributed Bragg reflector is configured to reflect light throughout the wavelength range.

Aspect 4. The semiconductor structure of any one of aspects 2 to 4, wherein the light absorbing region is configured to absorb radiation such as solar radiation within a portion of a wavelength range from 900 nm to 1,800 nm.

Aspect 5. The semiconductor structure of any one of aspects 2 to 4, further comprising: a first doped layer underlying the chirped distributed Bragg reflector; and a second doped layer overlying the light absorbing region.

Aspect 6. The semiconductor structure of aspect 5, wherein the first doped layer is n-type doped and the second doped layer is p-type doped.

Aspect 7. The semiconductor structure of any one of aspects 5 to 6, wherein the first doped layer is p-type doped and the second doped layer is n-type doped.

Aspect 8. The semiconductor structure of any one of aspects 2 to 7, wherein, the first doped layer is characterized by a first band gap; the second doped layer is characterized by a second band gap; the light absorbing region is characterized by a third band gap; and each of the first band gap and the second band gap is higher than the third band gap.

Aspect 9. The semiconductor structure of any one of aspects 5 to 8, wherein the chirped distributed Bragg reflector comprises a doping type that is the same as a doping type as the first doped layer.

Aspect 10. The semiconductor structure of any one of aspects 2 to 9, wherein the light absorbing region comprises a dilute nitride material.

Aspect 11. The semiconductor structure of any one of aspects 2 to 10, wherein the light absorbing region comprises GaInNAsSb, GaInNAsBi, or GaInNAsSbBi.

Aspect 12. The semiconductor structure of any one of aspects 2 to 11, wherein the light absorbing region is lattice matched to Ge or to GaAs.

Aspect 13. The semiconductor structure of any one of aspects 2 to 12, wherein the light absorbing region comprises Ga₁₋ₓInₓN_{y}As_{1-y-z}Sb_{z}, where x, y and z fall within the ranges 0≤x≤0.4, 0≤y≤0.1 and 0≤z≤0.2.

Aspect 14. The semiconductor structure of any one of aspects 2 to 13, wherein the light absorbing region is characterized by a band gap within a range from 0.7 eV to 1.2 eV.

Aspect 15. The semiconductor structure of any one of aspects 2 to 14, wherein the chirped distributed Bragg reflector is configured to reflect light at wavelengths that can be absorbed by the light absorbing region.

Aspect 16. The semiconductor structure of any one of aspects 2 to 15, wherein the chirped distributed Bragg reflector comprises a plurality of layers, wherein adjacent layers of the plurality of layers are characterized by a different refractive index and a different thickness.

Aspect 17. The semiconductor structure of aspect 16, wherein of each of the layers has a thickness that is an integer multiple of a quarter wavelength of a design wavelength.

Aspect 18. The semiconductor structure of any one of aspects 16 to 17, wherein each of the layers has a thickness that is an integer multiple of λ₀/4n where λ₀ is the design wavelength and n is the refractive index of the layer

Aspect 19. The semiconductor structure of any one of aspects 16 to 18, wherein each of the layers independently comprises AlAs, AlGaAs, GaAs, InAs, GaInAs, AlInAs, InGaP, AlInGaP, InGaP, GaP, InP, AlP, AlInP, or AlInGaAs.

Aspect 20. The semiconductor structure of any one of aspects 16 to 19, wherein the chirped distributed Bragg reflector is configured to transmit light at wavelengths higher than a low wavelength absorption cut-off wavelength of the overlying light absorbing layer.

Aspect 21. The semiconductor structure of any one of aspects 16 to 20, further comprising a graded interlayer between adjacent layers.

Aspect 22. The semiconductor structure of any one of aspects 2 to 21, wherein the chirped distributed Bragg reflector comprises two or more mirror pairs, wherein each of the two or more mirror pairs is characterized by a different design wavelength λ₀.

Aspect 23. The semiconductor structure of aspect 22, wherein each of the mirror pairs comprises the same materials and is characterized by a different thickness.

Aspect 24. The semiconductor structure of any one of aspects 22 to 23, wherein a thickness of each of the mirror pairs ranges from (1+C) λ₀/4n to (1−C) λ₀/4n, where C is the chirp fraction, λ₀ is the design wavelength, and n is the refractive index of a layer forming the mirror pair.

Aspect 25. The semiconductor structure of aspect 24, wherein the chirp fraction is within a range from 0.01 to 0.3.

Aspect 26. The semiconductor structure of any one of aspects 2 to 25, wherein the chirped distributed Bragg reflector comprises a first mirror pair and a second mirror pair.

Aspect 27. The semiconductor structure of any one of aspects 2 to 25, wherein the chirped distributed Bragg reflector comprises two or more first mirror pairs.

Aspect 28. The semiconductor structure of any one of aspects 2 to 25, wherein the chirped distributed Bragg reflector comprises two or more first mirror pairs, and two or more second mirror pairs.

Aspect 29. The semiconductor structure of any one of aspects 2 to 28, wherein the reflectivity of the chirped distributed Bragg reflector is characterized by a full-width-half-maximum within a range from 100 nm to 500 nm.

Aspect 30. The semiconductor structure of any one of aspects 2 to 28, wherein the reflectivity of the chirped distributed Bragg reflector is characterized by a full-width-half-maximum within a range from 250 nm to 450 nm.

Aspect 31. The semiconductor structure of any one of aspects 2 to 28, wherein the chirped distributed Bragg reflector is characterized by a reflectivity greater than 50% throughout an incident wavelength range of 850 nm to 1150 nm.

Aspect 32. The semiconductor structure of any one of aspects 2 to 31, wherein the chirped distributed Bragg reflector is characterized by a reflectivity greater than 50% throughout an incident wavelength range of 900 nm to 1200 nm.

Aspect 33. The semiconductor structure of any one of aspects 2 to 32, wherein the chirped distributed Bragg reflector is characterized by a normal peak reflectivity within a range from 900 nm (1.378 eV) to 1,400 nm (0.885 eV), from 900 nm (1.378 eV) to 1,300 nm (0.954 eV), from 900 nm (1.378 eV) to 1,200 nm (1.033 eV), or from 900 nm (1.378 eV) to 1,100 nm (1.127 eV).

Aspect 34. The semiconductor structure of any one of aspects 2 to 33, wherein the chirped distributed Bragg reflector is characterized by a normal peak reflectivity at least 50 nm less than a short wavelength absorption edge an underlying layer.

Aspect 35. The semiconductor structure of any one of aspects 2 to 34, wherein the chirped distributed Bragg reflector is characterized by a full-width-half-maximum greater than 100 nm.

Aspect 36. The semiconductor structure of any one of aspects 2 to 35, wherein the chirped distributed Bragg reflector is characterized by a long wavelength full-width-half maximum wavelength that is within 50 nm of the long wavelength absorption cutoff of the light absorbing layer.

Aspect 37. The semiconductor structure of any one of aspects 2 to 36, wherein the chirped distributed Bragg reflector is characterized by a reflectivity of greater than 50%, and an incident angle within a range from ±45 degrees from normal, at a wavelength throughout a range of greater than 100 nm, and a transmissibility greater than 80% at a wavelength that is 50 nm greater than the high end of the wavelength range.

Aspect 38. The semiconductor structure of any one of aspects 2 to 37, wherein the light absorbing region comprises an unintentionally doped region and an intentionally doped region.

Aspect 39. The semiconductor structure of any one of aspects 2 to 38, wherein the light absorbing region comprises an intentionally doped region, wherein the intentionally doped region comprises a non-linear doping profile.

Aspect 40. A multijunction photovoltaic cell comprising: the semiconductor structure of any one of aspects 2 to 39; a first doped layer underlying the chirped distributed Bragg reflector; and a second doped layer overlying the light absorbing region.

Aspect 41. The multijunction photovoltaic cell of aspect 40, further comprising at least one semiconductor layer, wherein the at least one semiconductor layer underlies the first doped layer.

Aspect 42. A semiconductor device comprising the semiconductor structure of any one of aspects 2 to 39.

Aspect 43. A multijunction photovoltaic cell comprising the semiconductor structure of any one of aspects 2 to 39.

Aspect 44. A photovoltaic module comprising the multijunction photovoltaic cell of aspect 43.

Aspect 45. A power system comprising the photovoltaic module of aspect 44.

Aspect 46. The semiconductor device of aspect 42, wherein the semiconductor device comprises a photodetector.

Aspect 1A. A semiconductor structure comprising: a light absorbing region comprising a high wavelength absorption edge; and a chirped distributed Bragg reflector underlying the light absorbing region, wherein the chirped distributed Bragg reflector is configured to provide: a reflectivity greater than 50% at an incident angle within a range of ±45 degrees from normal throughout; a full-width-half-maximum wavelength range of 100 nm or greater; and a transmissibility greater than 80% at a wavelength that is 50 nm longer than the high wavelength absorption edge of the overlying light absorbing region.

Aspect 2A. The semiconductor structure of aspect 1A, wherein, the light absorbing region is configured to absorb light within a portion of a wavelength range from 900 nm to 1,800 nm; and the chirped distributed Bragg reflector is configured to reflect light throughout the portion of the wavelength range.

Aspect 3A. The semiconductor structure of any one of aspects 1A to 2A, further comprising: a first doped semiconductor layer underlying the chirped distributed Bragg reflector; and a second doped semiconductor layer overlying the light absorbing region.

Aspect 4A. The semiconductor structure of aspect 3A, wherein, the first doped semiconductor layer is characterized by a first band gap; the second doped semiconductor layer is characterized by a second band gap; the light absorbing region is characterized by a third band gap; and each of the first band gap and the second band gap is greater than the third band gap.

Aspect 5A. The semiconductor structure of any one of aspects 1A to 4A, wherein the light absorbing region comprises a dilute nitride material.

Aspect 6A. The semiconductor structure of any one of aspects 1A to 5A, wherein the light absorbing region is characterized by a band gap within a range from 0.7 eV to 1.2 eV.

Aspect 7A. The semiconductor structure of any one of aspects 1A to 6A, wherein the chirped distributed Bragg reflector comprises a plurality of layers, wherein adjacent layers of the plurality of layers are characterized by a different refractive index and a different thickness.

Aspect 8A. The semiconductor structure of aspect 7A, further comprising a graded interlayer between adjacent layers of the plurality of layers.

Aspect 9A. The semiconductor structure of any one of aspects 1A to 8A, wherein the chirped distributed Bragg reflector is configured to transmit light at wavelengths longer than the high wavelength absorption edge of the overlying light absorbing region.

Aspect 10A. The semiconductor structure of any one of aspects 1A to 9A, wherein the chirped distributed Bragg reflector comprises two or more mirror pairs, wherein each of the two or more mirror pairs is characterized by a different design wavelength λ₀.

Aspect 11A. The semiconductor structure of aspect 10A, wherein, each of the two or more mirror pairs independently has a thickness within a range from (1+C) λ₀/4n to (1−C) λ₀/4n, where C is the chirp fraction, λ₀ is the design wavelength, and n is the refractive index of a layer forming the mirror pair; and the chirp fraction is within a range from 0.01 to 0.3.

Aspect 12A. The semiconductor structure of any one of aspects 1A to 11A, wherein the reflectivity of the chirped distributed Bragg reflector is characterized by a full-width-half-maximum within a range from 100 nm to 500 nm.

Aspect 13A. The semiconductor structure of any one of aspects 1A to 12A, wherein the chirped distributed Bragg reflector is characterized by a reflectivity greater than 50% throughout an incident wavelength range from 850 nm to 1150 nm.

Aspect 14A. The semiconductor structure of any one of aspects 1A to 13A, wherein the chirped distributed Bragg reflector is characterized by a normal peak reflectivity at a wavelength that is at least 50 nm less than a short wavelength absorption edge of an underlying light absorbing region.

Aspect 15A. The semiconductor structure of any one of aspects 1A to 14A, wherein the chirped distributed Bragg reflector is characterized by a long wavelength cut-off that is within 50 nm of the long wavelength absorption edge of the light absorbing layer.

Aspect 16A. The semiconductor structure of any one of aspects 1A to 15A, wherein the chirped distributed Bragg reflector is characterized by: a reflectivity of greater than 50% at an incident angle within a range from ±45 degrees from normal, throughout a wavelength range greater than 100 nm; and a transmissibility greater than 80% at a wavelength that is 50 nm longer than the longest wavelength of the wavelength range.

Aspect 17A. The semiconductor structure of any one of aspects 1A to 16A, wherein the light absorbing region comprises an unintentionally doped region and an intentionally doped region.

Aspect 18A. The semiconductor structure of any one of aspects 1A to 17A, wherein the chirped distributed Bragg reflector is configured to reflect light at wavelengths throughout the entire absorption range of the overlying light absorbing layer.

Aspect 19A. A multijunction photovoltaic cell comprising: the semiconductor structure of any one of aspects 1A to 18A; a first doped semiconductor layer underlying the chirped distributed Bragg reflector; and a second doped layer overlying the light absorbing region.

Aspect 20A. A semiconductor device comprising the semiconductor structure of any one of aspects 1A to 19A.

Aspect 21A. The semiconductor device of aspect 20A, wherein the semiconductor device comprises a photodetector.

Aspect 22A. The semiconductor device of any one of aspects 20A to 22A, wherein the chirped distributed Bragg reflector is configured to reflect light at wavelengths throughout the entire absorption range of the overlying light absorbing layer.

It should be noted that there are alternative ways of implementing the embodiments disclosed herein. Accordingly, the present embodiments are to be considered as illustrative and not restrictive. Furthermore, the claims are not to be limited to the details given herein and are entitled their full scope and equivalents thereof

What is claimed is:

1. A semiconductor structure comprising:
a light absorbing region comprising a high wavelength absorption edge; and
a chirped distributed Bragg reflector underlying the light absorbing region, wherein the chirped distributed Bragg reflector is configured to provide:
a reflectivity greater than 50% at an incident angle within a range of ±45 degrees from normal throughout;
a full-width-half-maximum wavelength range of 100 nm or greater; and
a transmissibility greater than 80% at a wavelength that is 50 nm longer than the high wavelength absorption edge of the overlying light absorbing region.

2. The semiconductor structure of claim 1, wherein,
the light absorbing region is configured to absorb light within a portion of a wavelength range from 900 nm to 1,800 nm; and
the chirped distributed Bragg reflector is configured to reflect light throughout the portion of the wavelength range.

3. The semiconductor structure of claim 1, further comprising:
a first doped semiconductor layer underlying the chirped distributed Bragg reflector; and
a second doped semiconductor layer overlying the light absorbing region.

4. The semiconductor structure of claim 3, wherein,
the first doped semiconductor layer is characterized by a first band gap;
the second doped semiconductor layer is characterized by a second band gap;
the light absorbing region is characterized by a third band gap; and
each of the first band gap and the second band gap is greater than the third band gap.

5. The semiconductor structure of claim 1, wherein the light absorbing region comprises a dilute nitride material.

6. The semiconductor structure of claim 1, wherein the light absorbing region is characterized by a band gap within a range from 0.7 eV to 1.2 eV.

7. The semiconductor structure of claim 1, wherein the chirped distributed Bragg reflector comprises a plurality of layers, wherein adjacent layers of the plurality of layers are characterized by a different refractive index and a different thickness.

8. The semiconductor structure of claim 7, further comprising a graded interlayer between adjacent layers of the plurality of layers.

9. The semiconductor structure of claim 1, wherein the chirped distributed Bragg reflector is configured to transmit light at wavelengths longer than the high wavelength absorption edge of the overlying light absorbing region.

10. The semiconductor structure of claim 1, wherein the chirped distributed Bragg reflector comprises two or more mirror pairs, wherein each of the two or more mirror pairs is characterized by a different design wavelength λ₀.

11. The semiconductor structure of claim 10, wherein,
each of the two or more mirror pairs independently has a thickness within a range from (1+C) λ₀/4n to (1−C) λ₀/4n, where C is the chirp fraction, λ₀ is the design wavelength, and n is the refractive index of a layer forming the mirror pair; and
the chirp fraction is within a range from 0.01 to 0.3.

12. The semiconductor structure of claim 1, wherein the reflectivity of the chirped distributed Bragg reflector is characterized by a full-width-half-maximum within a range from 100 nm to 500 nm.

13. The semiconductor structure of claim 1, wherein the chirped distributed Bragg reflector is characterized by a reflectivity greater than 50% throughout an incident wavelength range from 850 nm to 1150 nm.

14. The semiconductor structure of claim 1, wherein the chirped distributed Bragg reflector is characterized by a normal peak reflectivity at a wavelength that is at least 50 nm less than a short wavelength absorption edge of an underlying light absorbing region.

15. The semiconductor structure of claim 1, wherein the chirped distributed Bragg reflector is characterized by a long wavelength cut-off that is within 50 nm of the long wavelength absorption edge of the light absorbing layer.

16. The semiconductor structure of claim 1, wherein the chirped distributed Bragg reflector is characterized by:
a reflectivity of greater than 50% at an incident angle within a range from ±45 degrees from normal, throughout a wavelength range greater than 100 nm; and
a transmissibility greater than 80% at a wavelength that is 50 nm longer than the longest wavelength of the wavelength range.

17. The semiconductor structure of claim 1, wherein the light absorbing region comprises an unintentionally doped region and an intentionally doped region.

18. The semiconductor structure of claim 1, wherein the chirped distributed Bragg reflector is configured to reflect light at wavelengths throughout the entire absorption range of the overlying light absorbing layer.

19. A multijunction photovoltaic cell comprising:
the semiconductor structure of claim 1;
a first doped semiconductor layer underlying the chirped distributed Bragg reflector; and
a second doped layer overlying the light absorbing region.

20. A semiconductor device comprising the semiconductor structure of claim 1.

21. The semiconductor device of claim 20, wherein the semiconductor device comprises a photodetector.

22. The semiconductor device of claim 20, wherein the chirped distributed Bragg reflector is configured to reflect light at wavelengths throughout the entire absorption range of the overlying light absorbing layer.
